(19) United States
(12) Patent Application Publication
(10) Pub. No.: US 2025/0239207 A1
(43) Pub. Date: Jul. 24, 2025

(54) DISPLAY DEVICE

(71) Applicant: SAMSUNG DISPLAY CO., LTD., YONGIN-SI (KR)

(72) Inventors: Eui Myeong CHO, Yongin-si (KR); Yu Chol KIM, Yongin-si (KR); Hong Soo KIM, Yongin-si (KR); Jin Wook YANG, Yongin-si (KR); Seong Oh YEOM, Yongin-si (KR); Ja Kyoung JIN, Yongin-si (KR)

(21) Appl. No.: 18/799,176

(22) Filed: Aug. 9, 2024

(30) Foreign Application Priority Data
Jan. 19, 2024 (KR) 10-2024-0009051

(51) Int. Cl. G09G 3/32; G09G 3/20

(52) U.S. Cl. CPC G09G 3/32; G09G 3/2074; G09G 3/2096; G09G 2300/0452; G09G 2300/0819; G09G 2310/0297; G09G 2310/08; G09G 2330/021; G09G 2330/045

(57) ABSTRACT

A display device includes sub-pixel circuits disposed in a plurality of rows and a plurality of columns, light emitting elements are respectively connected to the sub-pixel circuits, output lines configured to carry a data signal to the sub-pixel circuits, and first scan lines and second scan lines configured to carry a scan signal to the sub-pixel circuits, wherein each of the output lines is commonly connected to sub-pixel circuits, among the sub-pixel circuits, disposed in different columns among the columns, each of the first scan lines is connected to first sub-pixel circuits of a corresponding row among the sub-pixel circuits, and each of the second scan lines is connected to second sub-pixel circuits of a corresponding row among the sub-pixel circuits, wherein the first sub-pixel circuits and the second sub-pixel circuits are alternately disposed in the corresponding row.

This application claims priority under 35 U.S.C. § 119 (a) to Korean Patent Application No. 10-2024-0009051, filed on Jan. 19, 2024, in the Korean Intellectual Property Office, the entire disclosure of which is herein incorporated by reference.

### BACKGROUND

### 1. Technical Field

The disclosure relates to a display device, and more particularly a display device having an arrangement of light emitting elements and sub-pixel circuits enabling efficient data driving.

### 2. Discussion of Related Art

Display devices have become an important connection medium between a user and information as information technology has developed. As a result, the use of display devices, such as liquid crystal displays device and organic light emitting display devices, is increasing.

Each pixel of a display device may emit light with a luminance corresponding to a data voltage supplied through a data line. The display device may display an image frame by a combination of light emissions of a plurality of pixels.

Generally, the display device may include a display unit for displaying the image frame and a display driver providing an interface for connecting the display device to a processor or controller. The display unit may include a scan driver and the plurality of pixels. The display driver may include a data driver outputting a data signal to data lines connected to the plurality of pixels and a timing controller. The timing controller may control the scan driver and the data driver.

The display device may display an image by outputting a scan signal to a scan line connected to a pixel. For example, the scan driver may supply the scan signal for selecting a pixel to which a data voltage is to be supplied among the plurality of pixels. The scan driver may be a shift register that may sequentially supply a scan signal having a turn-on level in units of a scan line.

### SUMMARY

Embodiments of the present invention may provide a display device capable of reducing power consumption and heat generation of a data driver. Embodiments of the present invention may provide a display device including a reduced number of transistors included in a display driver.

According to an embodiment of the disclosure, a display device includes a plurality of sub-pixel circuits disposed in a matrix form including a plurality of rows and a plurality of columns, a plurality of light emitting elements respectively connected to the plurality of sub-pixel circuits, and a plurality of first scan lines and a plurality of second scan lines configured to carry a scan signal to the plurality of sub-pixel circuits. Each of the plurality of output lines is commonly connected to sub-pixel circuits, among the plurality of sub-pixel circuits, disposed in different columns among the plurality of columns. Each of the plurality of first scan lines is connected to first sub-pixel circuits of a corresponding row among the plurality of sub-pixel circuits. Each of the plurality of second scan lines is connected to second sub-pixel circuits of a corresponding row among the plurality of sub-pixel circuits, wherein the first sub-pixel circuits and the second sub-pixel circuits are alternately disposed in the corresponding row.

In an embodiment, the display device includes a data driver outputting the data signal to the plurality of sub-pixel circuits through the plurality of output lines, and a scan driver outputting the scan signal to the plurality of sub-pixel circuits through the plurality of first scan lines and the plurality of second scan lines. The plurality of rows include m rows and the plurality of columns includes n columns. In addition, a number of the plurality of first scan lines may be m, a number of the plurality of second scan lines may be m, and the number of the plurality of output lines may be n/2. Meanwhile, during a horizontal period corresponding to a selected row among the plurality of rows, the scan driver may activate a voltage of a first scan line corresponding to the selected row among the plurality of first scan lines during a first period of the horizontal period, and activate a voltage of a second scan line corresponding to the selected row of the plurality of second scan lines during a second period different from the first period of the horizontal period. Here, m and n may be integers greater than or equal to 2.

In an embodiment, during the first period, data output to the plurality of output lines may be applied to a first sub-pixel circuit among the first sub-pixel circuits corresponding to the selected row, and during the second period, data output to the plurality of output lines may be applied to a second sub-pixel circuit among the second sub-pixel circuits corresponding to the selected row.

In an embodiment, the data driver may be configured to apply data corresponding to a first color to sub-pixel circuits connected to a first output line among the plurality of output lines.

In an embodiment, the data driver may be configured to apply data corresponding to a second color to sub-pixel circuits connected to a second output line among the plurality of output lines.

In an embodiment, the plurality of light emitting elements may be formed on the plurality of sub-pixel circuits, and an anode electrode connecting a light emitting element among the plurality of light emitting elements and a corresponding sub-pixel circuit may be disposed on at least two sub-pixel circuits of the plurality of sub-pixel circuits.

In an embodiment, the data driver may be configured to apply data corresponding to a same color to sub-pixel circuits connected to a first output line among the plurality of output lines and apply data corresponding to different colors to sub-pixel circuits connected to a second output line among the plurality of output lines.

In an embodiment, the plurality of light emitting elements may be formed on the plurality of sub-pixel circuits, and an anode electrode connecting a light emitting element among the plurality of light emitting elements and a corresponding sub-pixel circuit may be disposed on a sub-pixel circuit that is not connected to the light emitting element.

In an embodiment, the data driver may be configured to apply data corresponding to different colors to sub-pixel circuits connected to each of the plurality of output lines.

In an embodiment, the plurality of light emitting elements may be formed on the plurality of sub-pixel circuits, and the display device further comprises a plurality of anode electrodes connecting each of the plurality of light emitting elements and a respective sub-pixel circuit disposed directly adjacent thereto.

In an embodiment, the plurality of light emitting elements may be disposed in one of an RGBG structure or an RGB stripe structure.

According to another embodiment of the disclosure, a display device includes a data driver, a scan driver, and a pixel unit. The data driver outputs data to k output lines. The scan driver outputs a scan signal to m first scan lines and m second scan lines. The pixel unit is connected to the k output lines, first scan lines, and second scan lines. The pixel unit includes a plurality of sub-pixel circuits disposed in a matrix form including m rows and 2k columns, and a plurality of light emitting elements respectively connected to the plurality of sub-pixel circuits. An h-th output line among the k output lines is commonly connected to sub-pixel circuits positioned in a (2 h−1)-th column and a 2 h-th column among the plurality of sub-pixel circuits. An i-th first scan line among the first scan lines is connected to first sub-pixel circuits among sub-pixel circuits positioned in an i-th row. An i-th second scan line among the second scan lines is connected to second sub-pixel circuits among the sub-pixel circuits positioned in the i-th row, wherein the first sub-pixel circuits and the second sub-pixel circuits are alternately disposed in the i-th row. Here, m and n are integers greater than or equal to 2, k is an integer greater than or equal to 1, h is an integer greater than 0 and less than or equal to k, and i is an integer greater than 0 and less than or equal to m.

In an embodiment, the data driver may be configured to apply data corresponding to a same color during a plurality of horizontal periods to sub-pixel circuits connected to each of at least one output line among the k output lines.

In an embodiment, the plurality of light emitting elements may be formed on the plurality of sub-pixel circuits, and an anode electrode connecting a light emitting element among the plurality of light emitting elements and a corresponding sub-pixel circuit may be disposed on a sub-pixel circuit that is not connected to the light emitting element.

In an embodiment, the data driver may be configured to apply data corresponding to the same color during a plurality of horizontal periods to sub-pixel circuits connected to each of the k output lines.

In an embodiment, the plurality of light emitting elements may be formed on the plurality of sub-pixel circuits, and an anode electrode connecting a light emitting element among the plurality of light emitting elements and a corresponding sub-pixel circuit may be disposed on at least two sub-pixel circuits of the plurality of sub-pixel circuits that are not connected to the light emitting element.

In an embodiment, the data driver may be configured to apply data corresponding to different colors to sub-pixel circuits connected to each of the k output lines.

In an embodiment, the plurality of light emitting elements may be disposed in one of an RGBR structure or an RGB stripe structure.

According to another embodiment of the disclosure, a display device may include a plurality of sub-pixel circuits disposed in a matrix form including a plurality of rows and a plurality of columns, a plurality of light emitting elements respectively connected to the plurality of sub-pixel circuits, a data driver outputting a data signal to the plurality of sub-pixel circuits through a plurality of output lines, and a scan driver outputting a scan signal to the plurality of sub-pixel circuits through a plurality of first scan lines and a plurality of second scan lines, wherein each output line among the plurality of output lines is commonly connected to sub-pixel circuits of the plurality of sub-pixel circuits positioned in adjacent columns among the plurality of columns, each of the plurality of first scan lines is connected to first sub-pixel circuits of a corresponding row among the plurality of sub-pixel circuits, each of the plurality of second scan lines is connected to second sub-pixel circuits of a corresponding row among the plurality of sub-pixel circuits, wherein the first sub-pixel circuits and the second sub-pixel circuits are alternately disposed in the corresponding row, and an anode electrode connecting a light emitting element among the plurality of light emitting elements and a corresponding sub-pixel circuit is disposed on a sub-pixel circuit of the plurality of sub-pixel circuits that is not connected to the light emitting element.

In an embodiment, the anode electrode connecting the light emitting element and the corresponding sub-pixel circuit may be disposed on at least two sub-pixel circuits of the plurality of sub-pixel circuits that are not connected to the light emitting element

In accordance with the display device according to the disclosure, power consumption and heat generation of a data driver may be reduced and the number of transistors included in a display driver may be reduced.

### BRIEF DESCRIPTION OF THE DRAWINGS

The above and other features of the disclosure will become more apparent by describing in detail embodiments thereof with reference to the accompanying drawings, in which:

FIG. 1 is a diagram illustrating a display device according to an embodiment of the disclosure;

FIG. 2 is a diagram illustrating a sub-pixel of FIG. 1;

FIG. 3 is a diagram illustrating an embodiment of a pixel unit shown in FIG. 1;

FIG. 4 is a diagram illustrating a data line and a scan line connected to sub-pixel circuits shown in FIG. 3;

FIG. 5 is a timing diagram illustrating an operation of a display device according to an embodiment of the disclosure;

FIG. 6 is a diagram illustrating a display device according to another embodiment of the disclosure;

FIG. 7 is a diagram illustrating an embodiment of a pixel unit shown in FIG. 6;

FIG. 8 is a diagram illustrating an output line and a scan line connected to sub-pixel circuits shown in FIG. 7;

FIG. 9 is a timing diagram illustrating an operation of the display device of FIG. 7 and FIG. 8;

FIG. 10 is a diagram illustrating another embodiment of the pixel unit shown in FIG. 6;

FIG. 11 is a diagram illustrating an output line and a scan line connected to sub-pixel circuits shown in FIG. 10;

FIG. 12 is a timing diagram illustrating an operation of the display device of FIG. 10 and FIG. 11;

FIG. 13 is a diagram illustrating still another embodiment of the pixel unit shown in FIG. 6;

FIG. 14 is a diagram illustrating an output line and a scan line connected to sub-pixel circuits shown in FIG. 13;

FIG. 15 is a timing diagram illustrating an operation of the display device of FIG. 13 and FIG. 14;

FIG. 16 is a diagram illustrating further still another embodiment of the pixel unit shown in FIG. 6;

FIG. 17 is a diagram illustrating an output line and a scan line connected to sub-pixel circuits shown in FIG. 16;

FIG. 18 is a timing diagram illustrating an operation of the display device of FIG. 16 and FIG. 17;

FIG. 19 is a diagram illustrating further still another embodiment of the pixel unit shown in FIG. 6;

FIG. 20 is a diagram illustrating an output line and a scan line connected to sub-pixel circuits shown in FIG. 13; and

FIG. 21 is a timing diagram illustrating an operation of the display device of FIG. 16 and FIG. 17.

### DETAILED DESCRIPTION

Hereinafter, various embodiments of the disclosure will be described in detail with reference to the accompanying drawings so that those skilled in the art may carry out aspects of the disclosure. The disclosure may be implemented in various different forms and is not limited to embodiments described herein.

In order to clearly describe aspects of the disclosure, parts that are not related to the description may be omitted, and the same or similar elements may be denoted by the same reference numerals throughout the specification and the drawings.

In addition, sizes and thicknesses of each component shown in the drawings may be arbitrarily shown for convenience of description, and thus the disclosure is not necessarily limited to those shown in the drawings. In the drawings, thicknesses may be exaggerated to clearly express various layers and areas.

In addition, an expression “is the same” in the description may mean “is substantially the same” such that those of ordinary skill in the art may understand sameness. Other expressions may also be expressions in which “substantially” may be omitted.

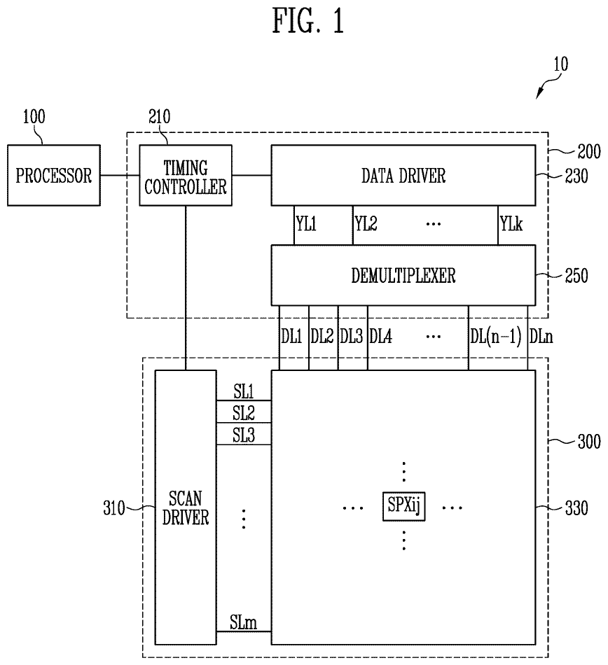

FIG. 1 is a diagram illustrating a display device according to an embodiment of the disclosure.

Referring to FIG. 1, the display device 10 according to an embodiment of the disclosure may include a processor 100, a display driver 200, and a display unit 300. The display driver 200 may include a timing controller 210, a data driver 230, and a demultiplexer 250. The display unit 300 may include a scan driver 310 and a pixel unit 330.

The timing controller 210 may receive grayscale values and timing signals for a frame period from the processor 100. Here, the processor 100 may correspond to at least one of a graphics processing unit (GPU), a central processing unit (CPU), or an application processor (AP). The timing signals may include a vertical synchronization signal, a horizontal synchronization signal, a data enable signal, or the like.

Each cycle of the vertical synchronization signal may correspond to a different frame period. Each cycle of the horizontal synchronization signal may correspond to a different horizontal period. The grayscale values may be supplied in a horizontal line unit in each horizontal period in response to an enable level of the data enable signal. The horizontal line may refer to pixels (for example, a pixel row) connected to a same scan line and a same emission line. For example, the horizontal line may refer to a selected row among the plurality of rows.

The timing controller 210 may render the grayscale values to correspond to a specification of the display device 10. For example, the processor 100 may provide a red grayscale value, a green grayscale value, and a blue grayscale value for each unit dot. For example, when the pixel unit 330 has an RGB stripe structure, the pixel may correspond to each grayscale value one-to-one. In a case where the pixels and the grayscale values corresponding to each other, one-to-one, rendering of the grayscale values may be omitted. However, for example, when the pixel unit 330 has a certain structure, such as an RGBG structure including green pixels interleaved with alternating red and blue pixels, or more particularly a PENTILE® structure, in which adjacent unit dots share a given pixel, the given pixel may not correspond to a grayscale value, one-to-one. In a case where the pixels and the grayscale values do not correspond to each other, one-to-one, the grayscale values may be rendered. The grayscale values may be provided to the data driver 230. The grayscale values may be provided to the data driver 230 whether the grayscale values are to be rendered or not. In addition, the timing controller 210 may provide a data control signal to the data driver 230. In addition, the timing controller 210 may provide a scan control signal to the scan driver 310.

The data driver 230 may generate data voltages (that is, data signals), and provide those data voltages to output lines YL1, YL2, . . . , and YLk using the grayscale values and the data control signal received from the timing controller 210. In this disclosure, k may be an integer greater than 0. At this time, the data signals output to the output lines YL1, YL2, . . . , and YLk may be multiplexed data signals. For example, the data signal output from the first output line YL1 may be selectively provided to a first data line DL1 and a second data line DL2. In addition, the data signal output from the second output line YL2 may be selectively provided to a third data line DL3 and a fourth data line DL4. In such a manner, the data signal output from the k-th output line YLk may be selectively provided to an (n−1)-th data line DLn−1 and an n-th data line DLn.

The demultiplexer 250 may demultiplex the data voltages output from the output lines YL1, YL2, . . . , and YLk and selectively provide the data voltages to the data lines DL1, DL2, DL3, DL4, . . . , and DLn. In an embodiment, demultiplexer 250 may be a 1:2 demultiplexer. In this case, the number n of data lines DL1, DL2, DL3, DL4, . . . , and DLn may be twice the number k of output lines YL1, YL2, . . . , and YLk. That is, a relationship “n=2k” may be established for the number of data lines and the number of output lines.

The scan driver 310 may generate scan signals to be provided to scan lines SL1, SL2, . . . , and SLm using the scan control signal (for example, a clock signal, a scan start signal, and the like) received from the timing controller 210. The scan driver 310 may sequentially supply scan signals having a turn-on level to the scan lines SL1 to SLm for selecting a pixel to which a data voltage may be supplied among the pixels. The scan driver 310 may include scan stages configured in a form of a shift register. The scan driver 310 may generate the scan signals in a method of sequentially transferring a scan start signal, which may be a pulse form of a turn-on level, to a next scan stage under control of the clock signal. In this disclosure, m may be an integer greater than 0.

The pixel unit 330 may include a plurality of sub-pixels. Each of the plurality of sub-pixels SPXij may be include a sub-pixel circuit and a light emitting element. Specifically, the pixel unit 330 may include sub-pixel circuits disposed in a matrix form having m rows and n columns. Each of the sub-pixel circuits may be connected to an anode of a corresponding light emitting element. Here, m and n may be integers greater than or equal to 2. Each sub-pixel SPXij may be connected to a corresponding data line and scan line. For example, the sub-pixel SPXij may be connected to an i-th scan line SLi and a j-th data line DLj. The sub-pixels may include sub-pixels emitting light of a first color, sub-pixels emitting light of a second color, and sub-pixels emitting light of a third color. The first color, the second color, and the third color may be different colors. For example, the first color may be red, green, or blue, the second color may be one other than the first color among red, green, and blue, and the third color may be one other than the first color and the second color among red, green, and blue. Embodiments are not limited to red, green, and blue. For example, magenta, cyan, and yellow may be used instead of red, green, and blue as the first to third colors.

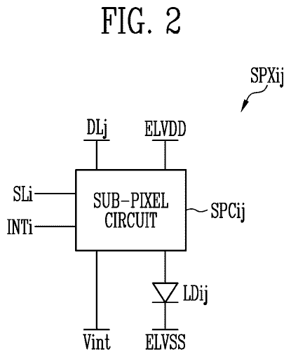

FIG. 2 is a diagram illustrating the sub-pixel of FIG. 1.

Referring to FIG. 2, the sub-pixel SPXij may include a sub-pixel circuit SPCij and a light emitting element LDij.

The sub-pixel circuit SPCij may include a plurality of transistors. In an embodiment, the sub-pixel circuit SPCij may include a driving transistor. According to a gate voltage of the driving transistor, a current applied to the light emitting element LDij may be controlled.

The sub-pixel circuit SPCij may include one or more capacitors. Since the sub-pixel circuit SPCij may be implemented in various ways, a detailed description of an implementation example of the sub-pixel circuit SPCij may be omitted in this specification.

The sub-pixel circuit SPCij may be connected to the scan line SLi, an initialization line INTi, and the data line DLj. In addition, the sub-pixel circuit SPCij may be connected to a first power line ELVDD, an initialization voltage line Vint, and a second power line ELVSS. In an embodiment, the gate voltage of the driving transistor may be initialized to a voltage of the initialization voltage line Vint by control of the initialization line INTi. As another example, a voltage of the anode electrode of the light emitting element LDij may be initialized by control of the initialization line INTi.

An anode of the light emitting element LDij may be connected to the sub-pixel circuit SPCij and a cathode may be connected to the second power line ELVSS. The light emitting element LDij may be a light emitting diode. The light emitting element LDij may be configured as an organic light emitting element (organic light emitting diode), an inorganic light emitting element (inorganic light emitting diode), a quantum dot/well light emitting element (quantum dot/well light emitting diode), or the like. The light emitting element LDij may emit light in the first color, the second color, or the third color, however the present disclosure is not limited thereto. For example, the light emitting element LDij may emit light selected from one or more colors, e.g., light selected from two colors or light selected from four colors. In addition, although one light emitting element LDij is described as being provided in each pixel in the example, the present disclosure is not limited thereto and a plurality of light emitting elements may be provided in each pixel. For example, the plurality of light emitting elements may be connected in series, parallel, series-parallel, or the like.

The first power line ELVDD may be supplied with a first power voltage, the second power line ELVSS may be supplied with a second power voltage, and the initialization voltage line Vint may be supplied with an initialization voltage. For example, the first power voltage may be greater than the second power voltage. For example, the initialization voltage may be greater than or equal to the second power voltage. For example, the initialization voltage may correspond to a data voltage having a smallest voltage among the data voltage(s) that may be provided. In another example, a magnitude of the initialization voltage may be less than a magnitude of the data voltages that may be provided.

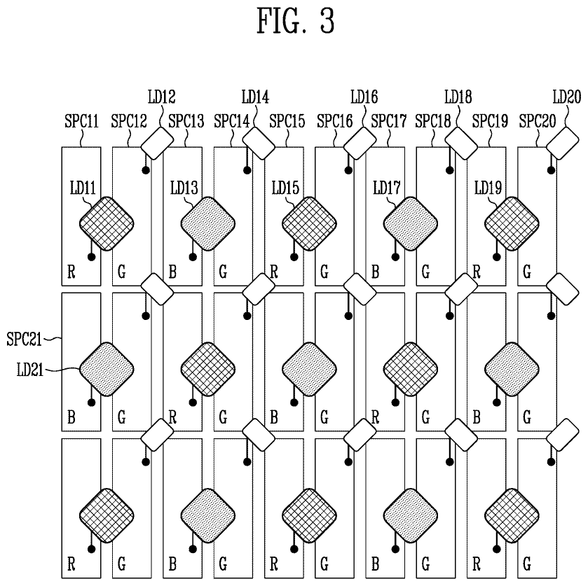

FIG. 3 is a diagram illustrating an embodiment of the pixel unit shown in FIG. 1.

Referring to FIG. 3, thirty sub-pixel circuits and thirty light emitting elements are shown. Specifically, sub-pixels and light emitting elements respectively corresponding thereto are shown in a matrix form including three rows and ten columns.

For example, ten sub-pixel circuits SPC11, SPC12, SPC13, . . . , and SPC20 may be disposed in a first row, and these sub-pixel circuits may be respectively connected to ten light emitting elements LD11, LD12, LD13, . . . , and LD20. In addition, ten sub-pixel circuits SPC21, . . . may be disposed in a second row, and these sub-pixel circuits may be respectively connected to ten light emitting elements LD21, . . . . Meanwhile, ten sub-pixel circuits may be disposed in a third row, and ten light emitting elements may be respectively connected to them. For convenience of description, reference numerals for the sub-pixel circuits after the first sub-pixel circuit SPC21 of the second row and the light emitting elements after the first light emitting element LD21 of the second row may be omitted in the drawings.

According to the pixel unit shown in FIG. 3, the light emitting elements forming the sub-pixel may be disposed in a diamond type configuration, such as the PENTILE structure. In FIG. 3, the light emitting elements may be formed on the sub-pixel circuits, and anode electrodes of the light emitting elements may be connected to corresponding sub-pixel circuits through contacts thereof.

In FIG. 3, a light emitting element that emits red light may be illustrated using a hatched pattern, a light emitting element that emits green light may be illustrated using white space (e.g., blank), and a light emitting element that emits blue light may be illustrated using a shaded or stippled pattern. In this specification, a sub-pixel including the light emitting element that emits red light and a sub-pixel circuit connected thereto may be referred to as a red sub-pixel. In addition, in this specification, a sub-pixel including the light emitting element that emits green light and a sub-pixel circuit connected thereto may be referred to as a green sub-pixel. Meanwhile, in this specification, a sub-pixel including the light emitting element that emits blue light and a sub-pixel circuit connected thereto may be referred to as a blue sub-pixel.

Meanwhile, in this specification, the sub-pixel circuit connected to the light emitting element that emits red light may be referred to as a red sub-pixel circuit, the sub-pixel circuit connected to the light emitting element that emits green light may be referred to as a green sub-pixel circuit, and the sub-pixel circuit connected to the light emitting element that emits blue light may be referred to as a blue sub-pixel circuit.

For example, among the light emitting elements LD11, LD12, LD13, . . . , and LD20 connected to the sub-pixel circuits SPC11, SPC12, SPC13, . . . , and SPC20 positioned in a first column, the light emitting elements LD11, LD15, and LD19 may emit red light, the light emitting elements LD12, LD14, LD16, and LD18 may emit green light, and the light emitting elements LD13 and LD17 may emit blue light. The sub-pixel circuits SPC11, SPC15, and SPC19 respectively connected to the light emitting elements LD11, LD15, and LD19 that emit red light may be marked with “R”, the sub-pixel circuits SPC12, SPC14, SPC16, and SPC18 connected to the light emitting elements LD12, LD14, LD16, and LD18 that emit green light may be marked with “G”, and the sub-pixel circuits SPC13 and SPC17 connected to the light emitting elements LD13 and LD17 that emit blue light may be marked with “B”. The same may be applied to sub-pixel circuits shown in a second column and a third column.

Referring to FIG. 3, the sub-pixel circuits positioned in the first row may be disposed in an order such that they may be connected to light emitting elements displaying colors of “R G B G R G B G R G”. In addition, the sub-pixel circuits positioned in the second row may be disposed in an order such that they may be connected to light emitting elements displaying colors of “B G R G B G R G B G”. Meanwhile, the sub-pixel circuits positioned in the third row may be disposed in an order such that they may be connected to light emitting elements displaying colors of “R G B G R G B G R G”, and this may be the same as the disposition of the sub-pixel circuits of the first row 1. Although not shown in FIG. 3, a disposition of sub-pixel circuits positioned in a fourth row may be the same as the disposition of the sub-pixel circuits positioned in the second row.

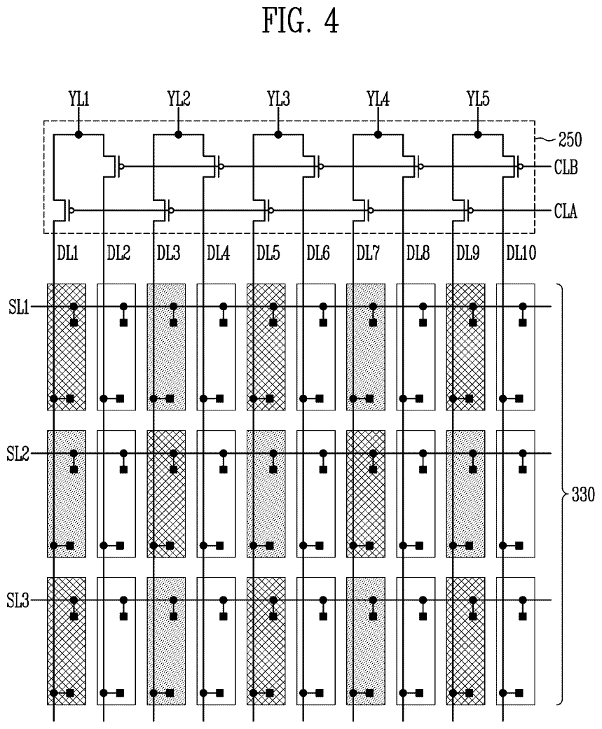

A data line and a scan line connected to each of the sub-pixel circuits shown in FIG. 3 are described with reference to FIG. 4.

FIG. 4 is a diagram illustrating the data line and the scan line connected to the sub-pixel circuits shown in FIG. 3.

Referring to FIG. 4, the thirty sub-pixel circuits shown in FIG. 3 are shown. For convenience of discussion, the light emitting elements may be omitted in FIG. 4. As described herein, the sub-pixel circuits positioned in the first row and the third row may be disposed in the order such that they may be connected to the light emitting elements that display the colors of “R G B GR GB GR G,” and the sub-pixel circuits positioned in the second row may be disposed in the order such that they may be connected to the light emitting elements that display the colors of “B G R G B G R G B G”. In FIG. 3, sub-pixel circuits connected to the light emitting element that emits red light may be illustrated using a hatched pattern, sub-pixel circuits connected to the light emitting element that emits green light may be illustrated using white space (e.g., blank), and sub-pixel circuits connected to the light emitting element that emits blue light may be illustrated using a shaded or stippled pattern. As described herein, each of the sub-pixel circuits form the sub-pixel, and these sub-pixel circuits may be included in the pixel unit 330.

A first data line DL1 may be connected to sub-pixel circuits positioned in a first column, and a second data line DL2 may be connected to sub-pixel circuits positioned in a second column. A third data line DL3 may be connected to sub-pixel circuits positioned in a third column, and a fourth data line DL4 may be connected to sub-pixel circuits positioned in a fourth column. In such a manner, data lines DL1 to DL10 may be connected to sub-pixel circuits positioned in a corresponding column.

A scan line SL1 corresponding to the first row may be connected to the sub-pixel circuits positioned in the first row, a scan line SL2 corresponding to the second row may be connected to the sub-pixel circuits positioned in the second row, and a scan line SL3 corresponding to the third row may be connected to the sub-pixel circuits positioned in the third row. In such a manner, the data line may be connected to sub-pixel circuits positioned in a corresponding column. In such a manner, the scan lines SL1 to SL3 may be connected to sub-pixel circuits positioned in a corresponding row.

Meanwhile, the demultiplexer 250 may be connected to the pixel unit 330 through the data lines. The demultiplexer 250 may selectively output the data signal output from output lines YL1 to YL5 to the data lines DL1 to DL10 based on a control signal from control signal lines CLA and CLB.

For example, during a first period, the first control signal line CLA may be activated and the second control signal line CLB may be deactivated. When the first control signal line CLA is activated and the second control signal line CLB is deactivated, transistors connected to the first control signal line CLA may be turned on and transistors connected to the second control signal line CLB may be turned off. Therefore, the demultiplexer 250 may output the data signal output from the output lines YL1 to YL5 to odd-numbered data lines DL1, DL3, DL5, DL7, and DL9.

Meanwhile, during a second period after the first period, the first control signal line CLA may be deactivated and the second control signal line CLB may be activated. When the first control signal line CLA is deactivated and the second control signal line CLB is activated, the transistors connected to the first control signal line CLA may be turned off and the transistors connected to the second control signal line CLB may be turned on. Therefore, the demultiplexer 250 may output the data signal output from the output lines YL1 to YL5 to even-numbered data lines DL2, DL4, DL6, DL8, and DL10.

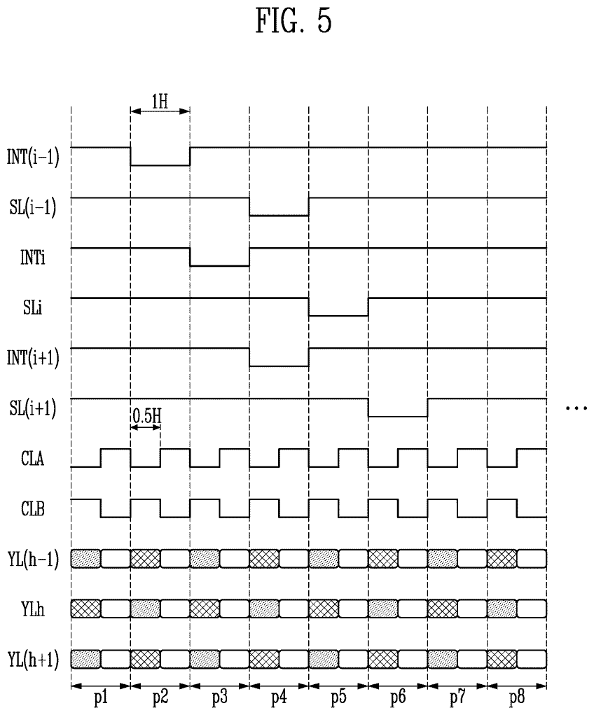

An operation of the demultiplexer shown in FIG. 3 and FIG. 4 and the pixel unit connected thereto is described with reference to FIG. 5.

FIG. 5 is a timing diagram illustrating an operation of a display device according to an embodiment of the disclosure.

Referring to FIG. 5, a timing diagram illustrating an operation of sub-pixel circuits positioned in an (i−1)-th row, an i-th row, and an (i+1)-th row during first to eighth periods p1 to p8 is shown. In FIG. 5, a length of each of the first to eighth periods p1 to p8 may correspond to one horizontal period 1H.

Specifically, in FIG. 5, signals of an initialization line INT(i−1) and a scan line SL(i−1) connected to the sub-pixel circuits of the (i−1)-th row, an initialization line INTi and a scan line SLi connected to the sub-pixel circuits of the i-th row, and an initialization line INT(i+1) and a scan line SL(i+1) connected to the sub-pixel circuits of the (i+1)-th row are shown. In addition, in FIG. 5, signals of the first control signal line CLA and the second control signal line CLB connected to the demultiplexer 250 are shown. Further, in FIG. 5, data signals output from an (h−1)-th output line YL(h−1), an h-th output line YLh, and an (h+1)-th output line YL(h+1) are shown. In FIG. 5, a data signal applied to the red sub-pixel circuit may be illustrated using a hatched pattern, a data signal applied to the green sub-pixel circuit may be illustrated using white space (e.g., blank), and a data signal applied to the blue sub-pixel circuit may be illustrated using a shaded or stippled pattern.

The demultiplexer 250 may selectively output the signal received from the (h−1)-th output line YL(h−1) to one of a (2 h−3)-th data line DL2(h −3) or a (2 h−2)-th data line DL2(h−2). In addition, the demultiplexer 250 may output the signal received from the h-th output line YLh to one of a (2 h−1)-th data line DL(2 h−1) or a 2 h-th data line DL(2 h). Meanwhile, the demultiplexer 250 may output the signal received from the (h+1)-th output line YL(h+1) to one of a (2 h+1)-th data line DL(2 h+1) or a (2 h+2)-th data line DL(2 h+2).

Referring to FIG. 5, in the first period p1, a voltage of initialization lines INT(i−1), INTi, and INT(i+1), and the scan lines SL(i−1), SLi, and SL(i+1) may be maintained at a high level.

In the second period p2, the voltage of the initialization line INT(i−1) connected to the sub-pixel circuits of the (i−1)-th row may be activated to a low level, and a gate voltage of a driving transistor included in the sub-pixel circuits of the (i−1)-th row may be initialized. For example, the (i−1)-th row may be selected. An initialized row may be referred to as a selected row.

In the third period p3, the voltage of the initialization line INTi connected to the sub-pixel circuits of the i-th row may be activated to a low level, and a gate voltage of a driving transistor included in the sub-pixel circuits of the i-th row may be initialized.

In the fourth period p4, the voltage of the scan line SLi−1 connected to the sub-pixel circuits of the (i−1)-th row may be activated to a low level, and in the fourth period p4, the data signals may be applied to the sub-pixel circuits of the (i−1)-th row. Specifically, in the fourth period p4, the gate voltage of the driving transistor included in the sub-pixel circuits of the (i−1)-th row may be changed to a voltage corresponding to a corresponding data signal.

At this time, during a 0.5 horizontal period 0.5H of the first half of the fourth period p4, the data signals from the output lines YL1 to YLk may be applied to sub-pixel circuits positioned in an odd column of the (i−1)-th row. During a 0.5 horizontal period 0.5H of the second half of the fourth period p4, the data signals from the output lines YL1 to YLk may be applied to sub-pixel circuits positioned in an even column of the (i−1)-th row. That is, a red data signal, a blue data signal, and a red data signal received from the output lines YL(h−1), YLh, and YL(h+1) during the 0.5 horizontal period 0.5H of the first half of the fourth period p4 may be respectively applied to the sub-pixel circuits connected to the data lines DL(2 h−3), DL2(h−1), and DL(2 h+1) among the sub-pixel circuits positioned in the (i−1)-th row. In addition, green data signals received from the output lines YL(h−1), YLh, and YL(h+1) during the 0.5 horizontal period 0.5H of the second half of the fourth period p4 may be respectively applied to the sub-pixel circuits connected to the data lines DL2(h−2), DL(2 h), and DL(2 h+2) among the sub-pixel circuits positioned in the (i−1)-th row.

In the fourth period p4, the voltage of the initialization line INT(i+1) connected to the sub-pixel circuits of the (i+1)-th row may be activated to a low level, and a gate voltage of a driving transistor included in the sub-pixel circuits of the (i+1)-th row may be initialized.

In the fifth period p5, the voltage of the scan line SLi connected to the sub-pixel circuits of the i-th row may be activated to a low level, and in the fifth period p5, the data signals may be applied to the sub-pixel circuits of the i-th row.

During a 0.5 horizontal period 0.5H of the first half of the fifth period p5, the data signals from the output lines YL1 to YLk may be applied to sub-pixel circuits positioned in an odd column of the i-th row. During a 0.5 horizontal period 0.5H of the second half of the fifth period p5, the data signals from the output lines YL1 to YLk may be applied to sub-pixel circuits positioned in an even column of the i-th row. That is, a blue data signal, a red data signal, and a blue data signal received from the output lines YL(h−1), YLh, and YL(h+1) during the 0.5 horizontal period 0.5H of the first half of the fifth period p5 may be respectively applied to the sub-pixel circuits connected to the data lines DL(2 h−3), DL2(h−1), and DL(2 h+1) among the sub-pixel circuits positioned in the i-th row. In addition, green data signals received from the output lines YL(h−1), YLh, and YL(h+1) during the 0.5 horizontal period 0.5H of the second half of the fifth period p5 may be respectively applied to the sub-pixel circuits connected to the data lines DL2(h−2), DL(2 h), and DL(2 h+2) among the sub-pixel circuits positioned in the i-th row.

Although not shown in FIG. 5, in the fifth period p5, the voltage of the initialization line INT(i+1) connected to sub-pixel circuits of an (i+2)-th row may be activated to a low level, and a gate voltage of a driving transistor included in the sub-pixel circuits of the (i+2)-th row may be initialized.

In the sixth period p6, the voltage of the scan line SLi connected to the sub-pixel circuits in the (i+1)-th row may be activated to a low level. Accordingly, in the sixth period p6, the data signals may be applied to the sub-pixel circuits of the (i+1)-th row.

During a 0.5 horizontal period 0.5H of the first half of the sixth period p6, the data signals from the output lines YL1 to YLk may be applied to sub-pixel circuits positioned in an odd column of the (i+1)-th row. During a 0.5 horizontal period 0.5H of the second half of the sixth period p6, the data signals from the output lines YL1 to YLk may be applied to sub-pixel circuits positioned in an even column of the (i+1)-th row. That is, a red data signal, a blue data signal, and a red data signal received from the output lines YL(h−1), YLh, and YL(h+1) during the 0.5 horizontal period 0.5H of the first half of the sixth period p6 may be respectively applied to the sub-pixel circuits connected to the data lines DL(2 h−3), DL2(h−1), and DL(2 h+1) among the sub-pixel circuits positioned in the (i+1)-th row. In addition, green data signals received from the output lines YL(h−1), YLh, and YL(h+1) during the 0.5 horizontal period 0.5H of the second half of the sixth period p6 may be respectively applied to the sub-pixel circuits connected to the data lines DL2(h−2), DL(2 h), and DL(2 h+2) among the sub-pixel circuits positioned in the (i+1)-th row.

In such a manner, in the seventh period p7 and the eighth period p8, the data signal from the output lines YL(h−1), YLh, and YL(h+1) may be applied to sub-pixel circuits connected to an (i+2)-th row and an (i+3)-th row, respectively.

According to an embodiment, and as shown in FIG. 3, FIG. 4, and FIG. 5, the number of output lines YL1 to YLk for outputting data from the data driver 230 may be half the number of data lines DL1 to DLn connected to the pixel unit 330. That is, the number of lines directly connected to the data driver 230 may be reduced. More particularly, the number of lines directly connected to the data driver 230 may be reduced to half the number of rows of the sub-pixels. However, according to the embodiment shown in FIG. 3, FIG. 4, and FIG. 5, since a voltage corresponding to the data signal is transmitted to the gate of the driving transistor of each of the sub-pixel circuits during a period 0.5H corresponding to half of one horizontal period 1H, a driving speed may be reduced. In addition, the demultiplexer 250 may be disposed between the data driver 230 and the pixel unit 330, and the number of transistors included in the demultiplexer 250 may be the same as the number of data lines DL1 to DLn. That is, since the demultiplexer 250, which includes a large number of transistors needed for operation of the display driver 200, an area occupied by the display driver 200 may be large and power consumed by the display driver 200 may be increased.

In addition, the data driver 230 may be configured to alternately output data signals corresponding to different colors for each period 0.5H corresponding to half of one horizontal period 1H for each of the output lines YL1 to YLk. That is, the data driver 230 may be configured to alternately output data signals corresponding to different colors such as red, green, blue, green, and the like (e.g., R G B G . . . ) for each of the output lines YL1 to YLk for each period 0.5 H corresponding to half of one horizontal period 1H. This means that even in a case where the display device outputs a still image or images (e.g., frames) that change little over time (hereinafter, a still video), the data signal output from the output lines YL1 to YLk may sharply change for each period 0.5H corresponding to half of one horizontal period 1H. Therefore, even in a case where a still image or a still video equivalent thereto is output, power consumed by the data driver 230 and heat generated from the data driver 230 may be high.

In accordance with a display device according to another embodiment of the disclosure, sub-pixel circuits corresponding to multiple columns may share each output line connected to the data driver, and the demultiplexer 250 may be omitted. For example, the sub-pixel circuits may correspond to two columns. In a case where the demultiplexer 250 and its transistors may be omitted, the area for manufacturing the display driver 200 may be reduced.

In addition, since the sub-pixel circuits may be directly connected to the k output lines YL1 to YLk, which number half the n data lines DL1 to DLn, the number of k output lines YL1 to YLk may be reduced.

In addition, according to an embodiment of the disclosure, a common output line among the output lines YL1 to YLk may output data to a plurality of the data lines DL1 to DLn corresponding to the same color. Similarly, according to an embodiment of the disclosure, a common output line among the output lines YL1 to YLk may output data corresponding to two different colors to a plurality of the data lines DL1 to DLn. In the case where a common output line among the output lines YL1 to YLk outputs data to at least two of the data lines DL1 to DLn, power consumed by the data driver and heat generated from the data driver may be reduced when outputting a still image or a still video equivalent thereto. In an embodiment, each output line among the output lines YL1 to YLk may be a common output line.

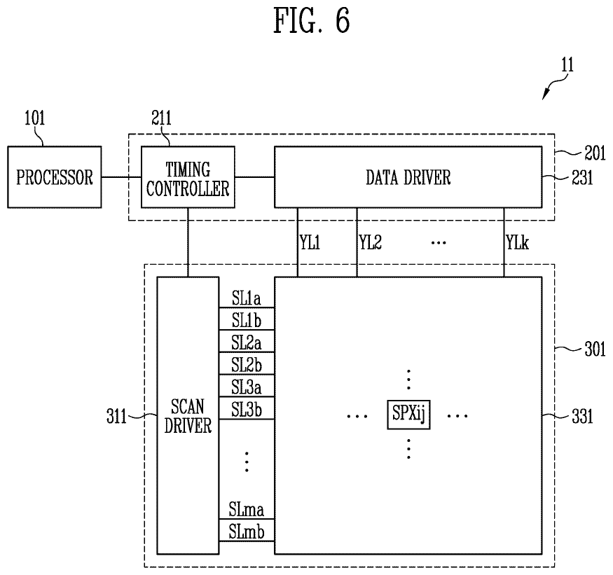

FIG. 6 is a diagram illustrating a display device according to another embodiment of the disclosure.

Referring to FIG. 6, the display device 11 according to an embodiment of the disclosure may include a processor 101, a display driver 201, and a display unit 301. The display driver 201 may include a timing controller 211 and a data driver 231. The display unit 301 may include a scan driver 311 and a pixel unit 331. Repetitive descriptions of components shown in FIG. 6 and described in connection with FIG. 1 may be omitted.

For example, the processor 101 and the timing controller 211 of FIG. 6 may be substantially the same as the processor 100 and the timing controller 210 of FIG. 1, and descriptions thereof may be omitted.

The data driver 231 may generate data voltages (that is, data signals) and provide the data voltages to the output lines YL1, YL2, . . . , and YLk using grayscale values and a data control signal received from the timing controller 211. The data signals output to the output lines YL1, YL2, . . . , and YLk may be multiplexed data signals. The data driver 231 may output data signals corresponding to a color. For example, the data driver 231 may output a data signal corresponding to up to two colors through at least one output line among the output lines YL1, YL2, . . . , and YLk using the grayscale values and the data control signal received from the timing controller 211.

The data driver 231 may be directly connected to the pixel unit 331 of the display unit 301 through the output lines YL1, YL2, . . . , and YLk. Among sub-pixels of the pixel unit 331, sub-pixels positioned in different columns may be connected to share an output line (i.e., a common output line). For example, sub-pixels positioned in two adjacent columns may be connected to share a common output line. In an embodiment, each output line among the output lines YL1 to YLk may be a common output line.

The scan driver 311 may generate scan signals and provide the scan signals to first scan lines SL1a, SL2a, . . . , and SLma and second scan lines SL1b, SL2b, . . . , and SLmb. The scan driver 311 may generate the scan signals and provide the scan signals to first scan lines SL1a, SL2a, . . . , and SLma and second scan lines SL1b, SL2b, . . . , and SLmb using a scan control signal (for example, a clock signal, a scan start signal, and the like) received from the timing controller 211. The scan driver 311 may supply scan signals to the first scan lines SL1a, SL2a, . . . , and SLma and the second scan lines SL1b, SL2b, . . . , and SLmb. The scan signals may have a turn-on level for selecting a pixel to which a data voltage may be supplied among the pixels.

The first scan lines SL1a, SL2a, . . . , and SLma may be respectively connected to odd-numbered sub-pixels among sub-pixels of a given row, and the second scan lines SL1b, SL2b, . . . , and SLmb may be respectively connected to even-numbered sub-pixels among the sub-pixels of the given row. For example, each of the plurality of first scan lines SL1a, SL2a, . . . , and SLma may be connected to first sub-pixel circuits of a corresponding row among the plurality of sub-pixel circuits, and each of the plurality of second scan lines SL1b, SL2b, . . . , and SLmb may be connected to second sub-pixel circuits of a corresponding row among the plurality of sub-pixel circuits, wherein the first sub-pixel circuits and the second sub-pixel circuits are alternately disposed in the corresponding row. That is, sub-pixels included in a same row may be connected to one of the first scan line or the second scan line. As shown in FIG. 1, the number of scan lines of a row direction may be m, while in the embodiment shown in FIG. 6, the number of scan lines of the row direction may be 2 m.

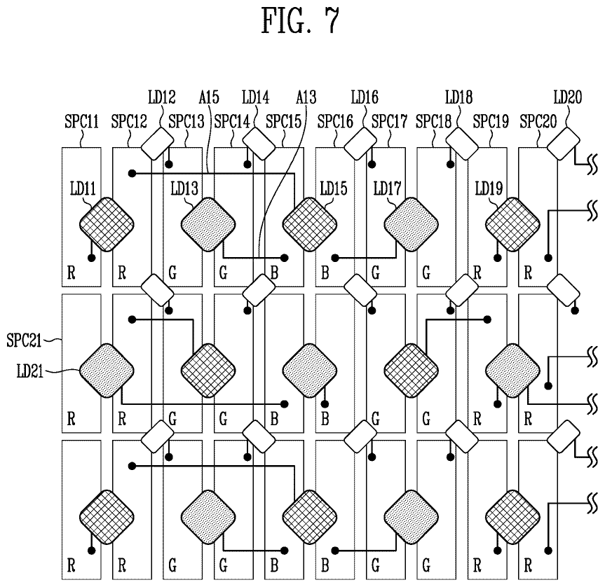

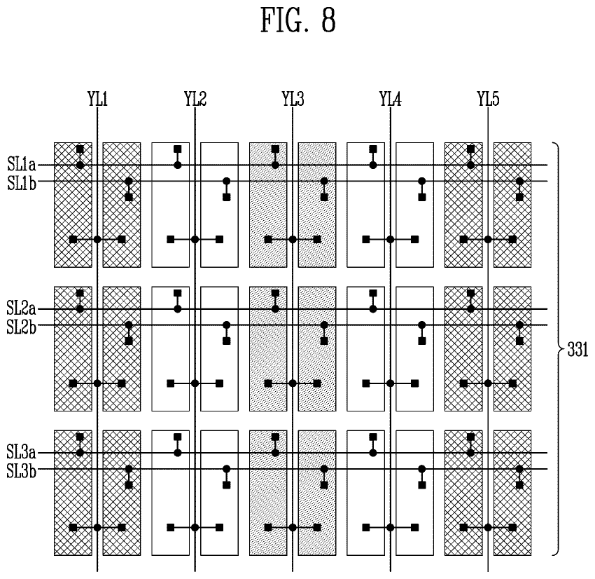

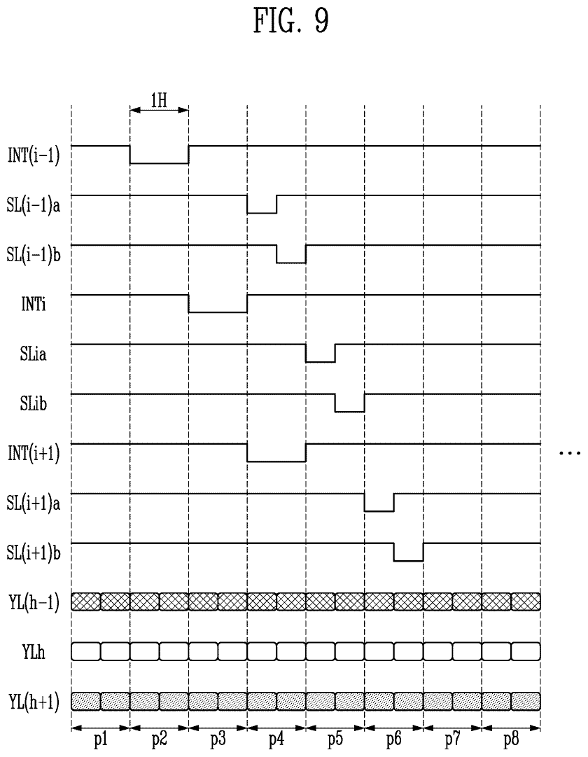

Hereinafter, an embodiment of the pixel unit 331 shown in FIG. 6 is described with reference to FIG. 7, FIG. 8, and FIG. 9.

FIG. 7 is a diagram illustrating an embodiment of the pixel unit shown in FIG. 6.

Referring to FIG. 7, thirty sub-pixel circuits and thirty light emitting elements are shown. Specifically, sub-pixels and light emitting elements respectively corresponding thereto are shown in a matrix form including three rows and ten columns.

For example, ten sub-pixel circuits SPC11, SPC12, SPC13, . . . , and SPC20 may be disposed in a first row, and these sub-pixel circuits may be respectively connected to ten light emitting elements LD11, LD12, LD13, . . . , and LD20. In addition, ten sub-pixel circuits SPC21, . . . may be disposed in a second row, and these sub-pixel circuits may be respectively connected to ten light emitting elements LD21, . . . . Meanwhile, ten sub-pixel circuits may be disposed in a third row, and ten light emitting elements may be respectively connected to them. For convenience of description, reference numerals for the sub-pixel circuits after the first sub-pixel circuit SPC21 of the second row and the light emitting elements after the first light emitting element LD21 of the second row may be omitted.

Similar to FIG. 3, according to the pixel unit shown in FIG. 7, the light emitting elements of the sub-pixel may be disposed in a diamond type configuration, such as a PENTILE structure.

Similar to FIG. 3, in FIG. 7, a light emitting element that emits red light may be illustrated using a hatched pattern, a light emitting element that emits green light may be illustrated using white space (e.g., blank), and a light emitting element that emits blue light may be illustrated using a shaded or stippled pattern.

According to the embodiment of FIG. 7, among the light emitting elements LD11, LD12, LD13, . . . , and LD20 connected to the sub-pixel circuits SPC11, SPC12, SPC13, . . . , and SPC20 positioned in a first column, the light emitting elements LD11, LD15, and LD19 may emit red light, the light emitting elements LD12, LD14, LD16, and LD18 may emit green light, and the light emitting elements LD13 and LD17 may emit blue light. The sub-pixel circuits SPC11, SPC12, and SPC19 respectively connected to the light emitting elements LD11, LD15, and LD19 that emit red light may be marked with “R”, the sub-pixel circuits SPC13, SPC14, SPC17, and SPC18 connected to the light emitting elements LD12, LD14, LD16, and LD18 that emit green light may be marked with “G”, and the sub-pixel circuits SPC15 and SPC16 connected to the light emitting elements LD13 and LD17 that emit blue light may be marked with “B”. The same may be applied to sub-pixel circuits shown in a second column and a third column.

Referring to FIG. 7, sub-pixel circuits positioned in the first, second, and third rows may be disposed in an order such that they may be connected to light emitting elements displaying colors of “R R G G B B G G R R”. Comparing FIG. 3, a position of the light emitting elements respectively outputting light of different colors may not be the same, but a position of a sub-pixel circuit connected to the corresponding light emitting elements may be changed. Therefore, a line connecting the light emitting elements and the sub-pixel circuits may be different.

For example, the anode electrode A13 connecting the light emitting element LD13 and the sub-pixel circuit corresponding thereto, i.e., the sub-pixel circuit SPC15, may be disposed on the sub-pixel circuits SPC14 that is not connected to the light emitting element LD13. In another example, the anode electrode A15 connecting the light emitting element LD15 and the sub-pixel circuit corresponding thereto, i.e., the sub-pixel circuit SPC12, may be disposed on the sub-pixel circuits SPC13, SPC14, and SPC15 that are not connected to the light emitting element LD15.

An output line and a scan line connected to each of sub-pixel circuits shown in FIG. 7 are described with reference to FIG. 8.

FIG. 8 is a diagram illustrating output lines and scan lines connected to the sub-pixel circuits shown in FIG. 7.

Referring to FIG. 8, the thirty sub-pixel circuits shown in FIG. 7 are shown. For convenience of discussion, the light emitting elements may be omitted in FIG. 8. As described herein, the sub-pixel circuits positioned in rows may be disposed in an order such that they may be connected to the light emitting elements that display the colors of “R R G G B B G G R R”. As described herein in connection with the pixel unit 330, the pixel unit 331 may include a plurality of sub-pixels, and each of the plurality of sub-pixels SPXij may be include a sub-pixel circuit and a light emitting element.

According to the embodiment shown in FIG. 8, the sub-pixel circuits may not be connected to the data line, and the sub-pixel circuits may be directly connected to the output lines YL1 to YL5. The output lines YL1 to YL5 may also be connected to the data driver 231. In particular, each of the output lines YL1 to YL5 may be commonly connected to sub-pixels corresponding to two columns.

Specifically, the first output line YL1 is connected to the sub-pixel circuits positioned in a first column and a second column. The second output line YL2 may be connected to the sub-pixel circuits positioned in a third column and a fourth column. The third output line YL3 may be connected to sub-pixel circuits positioned in a fifth column and a sixth column. In such a manner, each of the output lines YL1 to YL5 may be commonly connected to sub-pixel circuits positioned in a respective pair of columns. For example, each of the output lines YL1 to YL5 may be commonly connected to sub-pixel circuits positioned in the respective pair of columns, wherein the columns of the pair of columns may be adjacent columns.

The first scan line SL1a corresponding to the first row may be connected to odd-numbered sub-pixels among the sub-pixel circuits positioned in the first row, and the second scan line SL1b corresponding to the first row may be connected to even-numbered sub-pixels among the sub-pixel circuits positioned in the first row. The first scan line SL2a corresponding to the second row may be connected to odd-numbered sub-pixels among the sub-pixel circuits positioned in the second row, and the second scan line SL2b corresponding to the second row may be connected to even-numbered the sub-pixels among the sub-pixel circuits positioned in the second row. The first scan line SL3a corresponding to the third row may be connected to odd-numbered sub-pixels among the sub-pixel circuits positioned in the third row, and the second scan line SL3b corresponding to the third row may be connected to even-numbered sub-pixels among the sub-pixel circuits positioned in the third row. In such a manner, the first and second scan lines SL1a to SL3a and SL1b to SL3b may be connected to odd-numbered sub-pixel circuits or even-numbered sub-pixel circuits among sub-pixel circuits positioned in a corresponding row.

An operation of the pixel unit shown in FIG. 7 and FIG. 8 is described with reference to FIG. 9.

FIG. 9 is a timing diagram illustrating an operation of the display device according to the embodiment of FIG. 7 and FIG. 8.

Referring to FIG. 9, a timing diagram illustrating an operation of sub-pixel circuits positioned in an (i−1)-th row, an i-th row, and an (i+1)-th row during first to eighth periods p1 to p8 is shown.

Specifically, in FIG. 9, signals of an initialization line INT(i−1), a first scan line SL(i−1)a, and a second scan line SL(i−1)b connected to the sub-pixel circuits of the (i−1)-th row, an initialization line INTi, a first scan line SLia, and a second scan line SLib connected to the sub-pixel circuits of the i-th row, and an initialization line INT(i+1), a first scan line SL(i+1)a, and a second scan line SL(i+1)b connected to the sub-pixel circuits of the (i+1)-th row are shown. In addition, in FIG. 9, data signals output from an (h−1)-th output line YL(h−1), an h-th output line YLh, and an (h+1)-th output line YL(h+1) are shown. In FIG. 9, a data signal applied to the red sub-pixel circuit may be illustrated using a hatched pattern, a data signal applied to the green sub-pixel circuit is displayed may be illustrated using white space (e.g., blank), and a data signal applied to the blue sub-pixel circuit may be illustrated using a shaded or stippled pattern.

Referring to FIG. 9, in the first period p1, a voltage of initialization lines INT(i−1), INTi, and INT(i+1), the first scan lines SL(i−1)a, SLia, and SL(i+1)a, and second scan lines SL(i−1)b, SLib, and SL(i+1)b may be maintained at a high level.

In the second period p2, the voltage of the initialization line INT(i−1) connected to the sub-pixel circuits of the (i−1)-th row may be activated to a low level, and a gate voltage of a driving transistor included in the sub-pixel circuits of the (i−1)-th row may be initialized.

In the third period p3, the voltage of the initialization line INTi connected to the sub-pixel circuits of the i-th row may be activated to a low level, and a gate voltage of a driving transistor included in the sub-pixel circuits of the i-th row may be initialized.

During the first 0.5 horizontal period 0.5H of the first half of the fourth period p4, the voltage of the first scan line SL(i−1) a connected to odd-numbered pixel circuits among the sub-pixel circuits of the (i−1)-th row may be activated to a low level, and the data signals may be applied to odd-numbered sub-pixels among the sub-pixel circuits of the (i−1)-th row in the first 0.5 horizontal period 0.5H of the first half of the fourth period p4.

During the 0.5 horizontal period 0.5H of the second half of the fourth period p4, the voltage of the second scan line SL(i−1)b connected to even-numbered pixel circuits among the sub-pixel circuits of the (i−1)-th row may be activated to a low level, and the data signals may be applied to even-numbered sub-pixels among the sub-pixel circuits of the (i−1)-th row in the 0.5 horizontal period 0.5H of the second half of the fourth period p4.

That is, a red data signal, a green data signal, and a blue data signal received from the output lines YL(h−1), YLh, and YL(h+1) during the 0.5 horizontal period 0.5H of the first half of the fourth period p4 may be respectively applied to the odd-numbered sub-pixel circuits among the sub-pixel circuits positioned in the (i−1)-th row. In addition, a red data signal, a green data signal, and a blue data signal received from the output lines YL(h−1), YLh, and YL(h+1) during the 0.5 horizontal period 0.5H of the second half of the fourth period p4 may be respectively applied to the even-numbered sub-pixel circuits among the sub-pixel circuits positioned in the (i−1)-th row.

In the fourth period p4, the voltage of the initialization line INT(i+1) connected to the sub-pixel circuits of the (i+1)-th row may be activated to a low level, and a gate voltage of a driving transistor included in the sub-pixel circuits of the (i+1)-th row may be initialized.

During the first 0.5 horizontal period 0.5H of the first half of the fifth period p5, the voltage of the first scan line SLia connected to odd-numbered pixel circuits among the sub-pixel circuits of the i-th row may be activated to a low level, and the data signals may be applied to odd-numbered sub-pixels among the sub-pixel circuits of the i-th row in the first 0.5 horizontal period 0.5H of the first half of the fifth period p5.

During the 0.5 horizontal period 0.5H of the second half of the fifth period p5, the voltage of the second scan line SLib connected to even-numbered pixel circuits among the sub-pixel circuits of the i-th row may be activated to a low level, and the data signals may be applied to even-numbered sub-pixels among the sub-pixel circuits of the i-th row in the 0.5 horizontal period 0.5H of the second half of the fifth period p5.

That is, a red data signal, a green data signal, and a blue data signal received from the output lines YL(h−1), YLh, and YL(h+1) during the 0.5 horizontal period 0.5H of the first half of the fifth period p5 may be respectively applied to the odd-numbered sub-pixel circuits among the sub-pixel circuits positioned in the i-th row. In addition, a red data signal, a green data signal, and a blue data signal received from the output lines YL(h−1), YLh, and YL(h+1) during the 0.5 horizontal period 0.5H of the second half of the fifth period p5 may be respectively applied to the even-numbered sub-pixel circuits among the sub-pixel circuits positioned in the i-th row.

In the fifth period p5, the voltage of the initialization line INT(i+1) connected to sub-pixel circuits of the (i+1)-th row may be activated to a low level, and a gate voltage of a driving transistor included in the sub-pixel circuits of the (i+1)-th row may be initialized.

In a similar manner, a red data signal, a green data signal, and a blue data signal received from the output lines YL(h−1), YLh, and YL(h+1) during the 0.5 horizontal period 0.5H of the first half of the sixth period p6 may be respectively applied to odd-numbered sub-pixel circuits among the sub-pixel circuits positioned in the (i+1)-th row. In addition, a red data signal, a green data signal, and a blue data signal received from the output lines YL(h−1), YLh, and YL(h+1) during the 0.5 horizontal period 0.5H of the second half of the sixth period p6 may be respectively applied to even-numbered sub-pixel circuits among the sub-pixel circuits positioned in the (i+1)-th row.

In the subsequent seventh period p7 and eighth period p8, the data signal from the output lines YL(h−1), YLh, and YL(h+1) may be applied to sub-pixel circuits connected to an (i+2)-th row and an (i+3)-th row, respectively.

As shown in FIG. 6, FIG. 7, FIG. 8, and FIG. 9, sub-pixel circuits corresponding to two columns may share each of the output lines connected to the data driver 251, without a demultiplexer being disposed between the data driver and the pixel unit. In a case where the demultiplexer and its transistors may be omitted, the area for manufacturing the display driver 201 may be reduced.

In addition, since the sub-pixel circuits may be directly connected to the k output lines YL1 to YLk, which may number half the n data lines DL1 to DLn, instead of the n data lines DL1 to DLn, a number of lines arranged in a vertical direction may be reduced.

In addition, as shown in FIG. 7, FIG. 8, and FIG. 9, each of the output lines YL1 to YLk outputs data corresponding to the same color. That is, sub-pixel circuits of two columns connected to one output line may be connected to light emitting elements that output light of the same color, and when outputting a still image or a still video equivalent thereto, power consumed by the data driver 231 and heat generation from the data driver 231 may be reduced.

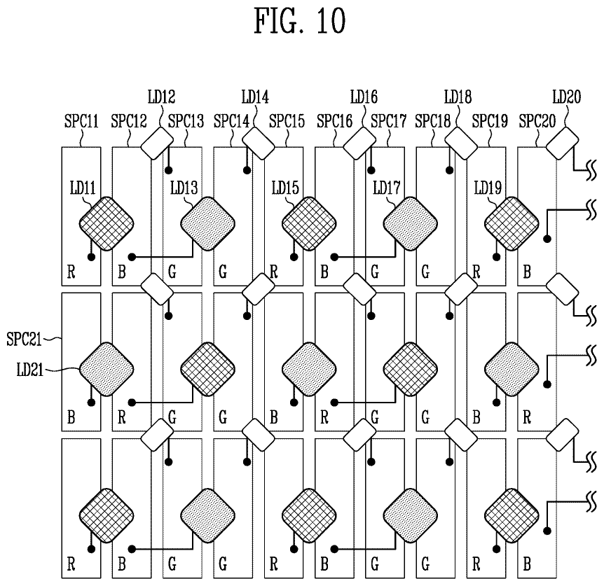

FIG. 10 is a diagram illustrating an embodiment of the pixel unit shown in FIG. 6.

Referring to FIG. 10, thirty sub-pixel circuits and thirty light emitting elements are shown.

Similar to FIG. 3 and FIG. 7, in FIG. 10, a light emitting element that emits red light may be illustrated using a hatched pattern, a light emitting element that emits green light may be illustrated as white space (e.g., blank), and a light emitting element that emits blue light may be illustrated by a shaded or stippled pattern.

According to an embodiment and as shown in FIG. 10, among the light emitting elements LD11, LD12, LD13, . . . , and LD20 connected to the sub-pixel circuits SPC11, SPC12, SPC13, . . . , and SPC20 positioned in a first column, the light emitting elements LD11, LD15, and LD19 may emit red light, the light emitting elements LD12, LD14, LD16, and LD18 may emit green light, and the light emitting elements LD13 and LD17 may emit blue light. The sub-pixel circuits SPC11, SPC15, and SPC19 respectively connected to the light emitting elements LD11, LD15, and LD19 that emit red light may be marked with “R”, the sub-pixel circuits SPC13, SPC14, SPC17, and SPC18 connected to the light emitting elements LD12, LD14, LD16, and LD18 that emit green light may be marked with “G”, and the sub-pixel circuits SPC12 and SPC16 connected to the light emitting elements LD13 and LD17 that emit blue light may be marked with “B”. The same is applied to sub-pixel circuits shown in a second column and a third column.

Referring to FIG. 10, sub-pixel circuits positioned in an odd-numbered row may be disposed in an order such that they may be connected to light emitting elements that display colors of “R B G G R B G G R B,” and sub-pixel circuits positioned in an even-numbered row may be disposed in an order such that they may be connected to light emitting elements that display colors of “B R G G B R G G B R”.

Comparing FIG. 7 and FIG. 10, in a case of FIG. 7, sub-pixel circuits positioned in two adjacent columns may be connected to light emitting elements of the same color so that the output lines output data corresponding to the same color. In a case of a common sub-pixel, a line for connecting the sub-pixel circuit and the anode of the light emitting element may be long. For example, in FIG. 7, a line may be formed across two sub-pixel circuits SPC13 and SPC14 so that the light emitting element LD15 that outputs red light may be connected to the sub-pixel circuit SPC12. In addition, a line connected to the light emitting element LD21 that outputs blue light may also cross two sub-pixel circuits.

In a case of FIG. 10, when one output line is configured to output data corresponding to red and blue alternately, and one output line is configured to output data corresponding to green equally, the line connecting the light emitting elements and the sub-pixel circuits may be simplified. Referring to FIG. 10, although a portion of a line connecting the blue light emitting element LD13 and the blue sub-pixel circuit SPC12 corresponding thereto is formed on another sub-pixel circuit SPC13, a case where a line connecting each light emitting element and a corresponding sub-pixel circuit crosses two sub-pixel circuits does not occur. Therefore, even in the diamond type configuration of the PENTILE structure, the line connecting light emitting elements and the sub-pixel circuits may be simplified. However, in this case, since data corresponding to different colors may need to be toggled and output in a common output line, heat generation from the data driver 231 may be high.

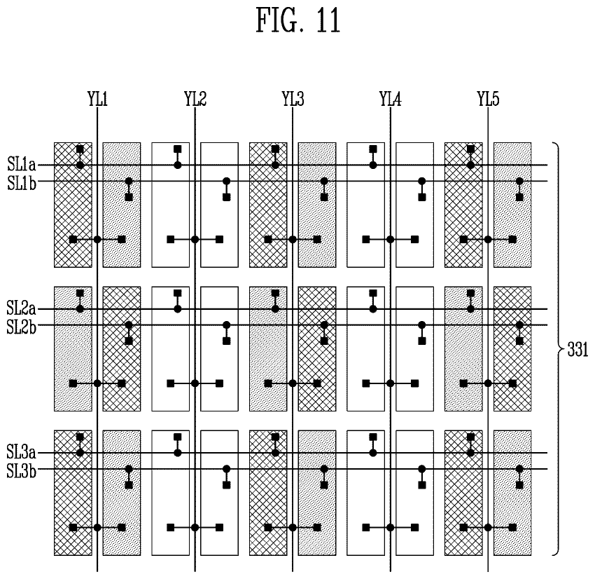

A data line and a scan line connected to each of the sub-pixel circuits shown in FIG. 10 are described with reference to FIG. 11.

FIG. 11 is a diagram illustrating the output line and the scan line connected to the sub-pixel circuits shown in FIG. 10.

Referring to FIG. 11, the thirty sub-pixel circuits shown in FIG. 10 are shown. As described herein, the sub-pixel circuits positioned in the odd-numbered row may be disposed in an order such that they may be connected to the light emitting elements that display the colors of “R B G G R B G G R B”, and the sub-pixel circuits positioned in the even-numbered row may be disposed in an order such that they may be connected the light emitting elements that display the colors of “B R G G B R G G B R”.

According to an embodiment and as shown in FIG. 11, a connection relationship between the output lines YL1 to YL5 and each of the sub-pixel circuits may be the same as that shown in FIG. 8. In addition, as shown in FIG. 11, a connection relationship between the first scan lines SL1a, SL2a, and SL3a and the second scan lines SL1b, SL2b, and SL3b, and each of the sub-pixel circuits may also be the same as that shown in FIG. 8. However, the light emitting element to which each of the sub-pixel circuits is connected may be different from that shown in FIG. 7 and FIG. 8. In an embodiment and as shown in FIG. 8, all sub-pixel circuits of the first column and the second columns may be connected to the light emitting element that emits red light. The same may apply to the sub-pixel circuits of a ninth column and a tenth column. However, in an embodiment and as shown in FIG. 11, an odd-numbered sub-pixel circuit among the sub-pixel circuits of the first column and the ninth column and an even-numbered sub-pixel circuit among the sub-pixel circuits of the second column and the tenth column may be connected to the light emitting element that emits red light, and an even-numbered sub-pixel circuit among the sub-pixel circuits of the first column and the ninth column and an odd-numbered sub-pixel circuit among the sub-pixel circuits of the second column and the tenth column may be connected to the light emitting element that emits blue light.

Meanwhile, structures illustrated in FIGS. 8 and 11 may be the same in that all of sub-pixel circuits of a third column and a fourth column and sub-pixel circuits of a seventh column and an eighth column may be connected to the light emitting element that emits green light.

In addition, as shown in FIG. 8, all sub-pixel circuits of a fifth column and a sixth column may be connected to the light emitting element that emits blue light. However, as shown in FIG. 11, an odd-numbered sub-pixel circuit among the sub-pixel circuits of the fifth column and an even-numbered sub-pixel circuit among the sub-pixel circuits of the sixth column may be connected to the light emitting element that emits red light, and an even-numbered sub-pixel circuit among the sub-pixel circuits of the fifth column and an odd-numbered sub-pixel circuit among the sub-pixel circuits of the sixth column may be connected to the light emitting element that emits blue light.

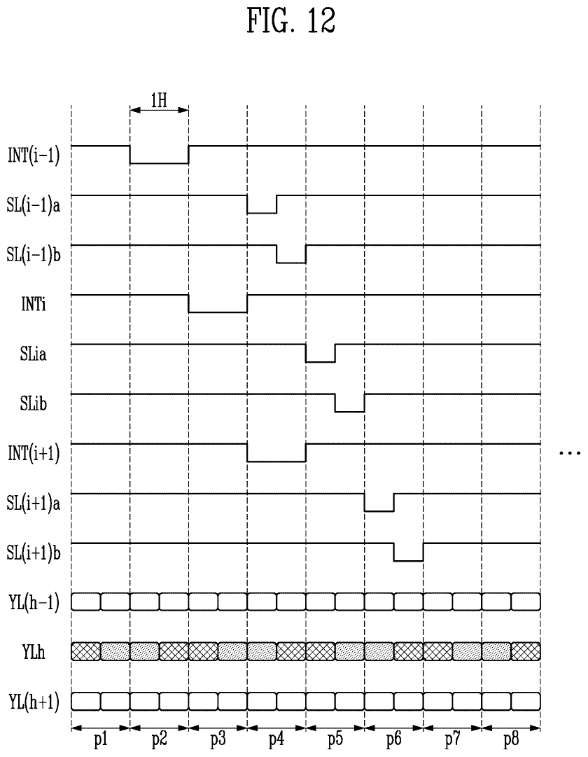

An operation of the pixel unit shown in FIG. 10 and FIG. 11 is described with reference to FIG. 12.

FIG. 12 is a timing diagram illustrating an operation of the display device according to the embodiment of FIG. 10 and FIG. 11.

Referring to FIG. 12, signals of an initialization line INT(i−1), a first scan line SL(i−1)a, and a second scan line SL(i−1)b connected to the sub-pixel circuits of the (i−1)-th row, an initialization line INTi, a first scan line SLia, and a second scan line SLib connected to the sub-pixel circuits of the i-th row, and an initialization line INT(i+1), a first scan line SL(i+1)a, and a second scan line SL(i+1)b connected to the sub-pixel circuits of the (i+1)-th row may be the same as those shown in FIG. 9. Therefore, redundant descriptions overlapping those of FIG. 9 may be omitted. For example, a description of the first to third periods p1 to p3 may be omitted.

Referring to FIG. 12, a green data signal, a blue data signal, and a green data signal received from the output lines YL(h−1), YLh, and YL(h+1) during the 0.5 horizontal period 0.5H of the first half of the fourth period p4 may be respectively applied to the odd-numbered sub-pixel circuits among the sub-pixel circuits positioned in the (i−1)-th row. In addition, a green data signal, a blue data signal, and a green data signal received from the output lines YL(h−1), YLh, and YL(h+1) during the 0.5 horizontal period 0.5H of the second half of the fourth period p4 may be respectively applied to the even-numbered sub-pixel circuits among the sub-pixel circuits positioned in the (i−1)-th row.

In addition, a green data signal, a red data signal, and a green data signal received from the output lines YL(h−1), YLh, and YL(h+1) during the 0.5 horizontal period 0.5H of the first half of the fifth period p5 may be respectively applied to the odd-numbered sub-pixel circuits among the sub-pixel circuits positioned in the i-th row. In addition, a green data signal, a blue data signal, and a green data signal received from the output lines YL(h−1), YLh, and YL(h+1) during the 0.5 horizontal period 0.5H of the second half of the fifth period p5 may be respectively applied to the even-numbered sub-pixel circuits among the sub-pixel circuits positioned in the i-th row.

In a similar manner, a green data signal, a blue data signal, and a green data signal received from the output lines YL(h−1), YLh, and YL(h+1) during the 0.5 horizontal period 0.5H of the first half of the sixth period p6 may be respectively applied to odd-numbered sub-pixel circuits among the sub-pixel circuits positioned in the (i+1)-th row. In addition, a green data signal, a red data signal, and a green data signal received from the output lines YL(h−1), YLh, and YL(h+1) during the 0.5 horizontal period 0.5H of the second half of the sixth period p6 may be respectively applied to even-numbered sub-pixel circuits among the sub-pixel circuits positioned in the (i+1)-th row.

In the subsequent seventh period p7 and eighth period p8, the data signal from the output lines YL(h−1), YLh, and YL(h+1) may be applied to sub-pixel circuits connected to an (i+2)-th row and an (i+3)-th row, respectively.

According to an embodiment and as shown in FIG. 6, FIG. 10, FIG. 11, and FIG. 12, sub-pixel circuits corresponding to two columns may share each of the output lines YL1 to YLk connected to the data driver 251, without a demultiplexer disposed between the data driver and the pixel unit. In a case where the demultiplexer and its transistors may be omitted, the area for manufacturing the display driver 201 may be reduced.

In addition, since the sub-pixel circuits may be directly connected to the k output lines YL1 to YLk, which number half the n data lines DL1 to DLn, instead of the n data lines DL1 to DLn, a number of lines arranged in a vertical direction may be reduced.

Meanwhile, according to an embodiment and as shown in FIG. 10, FIG. 11, and FIG. 12, a line connecting each light emitting element and a corresponding sub-pixel circuit that may cross two sub-pixel circuits may be omitted. Therefore, even in the diamond type configuration of the PENTILE structure, the line connecting the light emitting elements and the sub-pixel circuits may be simplified.

However, as shown in FIG. 10, FIG. 11, and FIG. 12, a common output line among the output lines YL1 to YLk may output data corresponding to the same color, for example, green. Meanwhile, another common output line among the output lines YL1 to YLk may output data corresponding to two colors, for example, red and blue, alternately for each 0.5 horizontal period 0.5H.

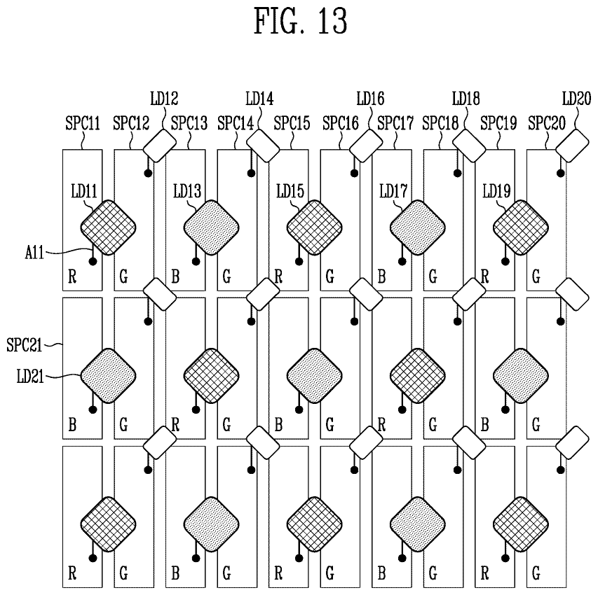

FIG. 13 is a diagram illustrating still another embodiment of the pixel unit shown in FIG. 6.

Referring to FIG. 13, a connection relationship between the light emitting element and a corresponding pixel circuit may be substantially the same as that shown in FIG. 3. As shown in FIG. 13, each of the light emitting elements may be connected to a directly adjacently positioned pixel circuit thereunder. Therefore, a line connecting each of the light emitting elements and the corresponding sub-pixel circuit may not cross an upper portion of another sub-pixel circuit. For example, an anode electrode may connect each of the plurality of light emitting elements and a respective sub-pixel circuit disposed directly adjacent thereto. For example, anode electrode A11 may connect light emitting element LD11 and sub-pixel circuit SPC11 disposed directly adjacent thereto. Therefore, even in the diamond type configuration of the PENTILE structure, complexity of a line connection connecting the light emitting elements and the sub-pixel circuits may be reduced.

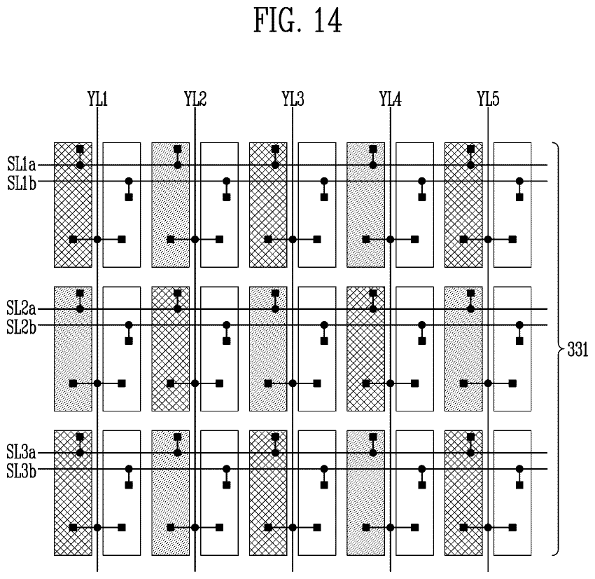

FIG. 14 is a diagram illustrating an output line and a scan line connected to the sub-pixel circuits shown in FIG. 13.

Referring to FIG. 14, the thirty sub-pixel circuits shown in FIG. 13 are shown. Referring to FIG. 13 and FIG. 14, the sub-pixel circuits positioned in the odd-numbered row may be disposed in an order such that they may be connected to light emitting elements that display colors of “R G B G R G B G R G”, and the sub-pixel circuits positioned in the even-numbered row may be disposed in an order such that they may be connected to light emitting elements that display colors of “B G R G B G R G B G”.

As shown in FIG. 14, the connection relationship between the output lines YL1 to YL5 and each of the sub-pixel circuits may be the same as that shown in FIG. 8 and FIG. 11. In addition, according to an embodiment, and as shown in FIG. 14, the connection relationship between the first scan lines SL1a, SL2a, and SL3a and the second scan lines SL1b, SL2b, and SL3b, and each of the sub-pixel circuits may be the same as that shown in FIG. 8 and FIG. 11. However, as shown in FIG. 14, the light emitting element to which each of the sub-pixel circuits is connected may be different from that shown in FIG. 7 and FIG. 8 or FIG. 10 and FIG. 11. Instead, a connection relationship between each of the sub-pixel circuits and the light emitting elements, as shown in FIG. 14, may be substantially the same as that shown in FIG. 3 and FIG. 4.

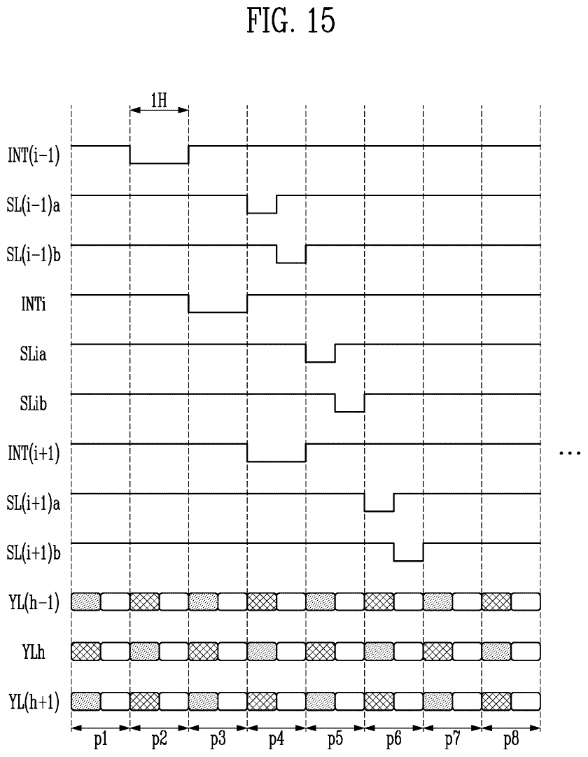

An operation of the pixel unit shown in FIG. 13 and FIG. 14 is described with reference to FIG. 15.

FIG. 15 is a timing diagram illustrating an operation of the display device according to the embodiment of FIG. 13 and FIG. 14.

Referring to FIG. 15, signals of an initialization line INT(i−1), a first scan line SL(i−1)a, and a second scan line SL(i−1)b connected to the sub-pixel circuits of the (i−1)-th row, an initialization line INTi, a first scan line SLia, and a second scan line SLib connected to the sub-pixel circuits of the i-th row, and an initialization line INT(i+1), a first scan line SL(i+1)a, and a second scan line SL(i+1)b connected to the sub-pixel circuits of the (i+1)-th row may be the same as those shown in FIG. 9 or FIG. 12. Therefore, redundant descriptions overlapping those of FIG. 9 or FIG. 12 may be omitted. For example, a description of the first to third periods p1 to p3 may be omitted.

Referring to FIG. 15, during the 0.5 horizontal period 0.5H of the first half of the fourth period p4, the data signals from the output lines YL1 to YLk may be applied to the sub-pixel circuits positioned in the odd column of the (i−1)-th row, and during the 0.5 horizontal period 0.5H of the second half of the fourth period p4, the data signals from the output lines YL1 to YLk may be applied to the sub-pixel circuits positioned in the even column of the (i−1)-th row. That is, a red data signal, a blue data signal, and a red data signal received from the output lines YL(h−1), YLh, and YL(h+1) during the 0.5 horizontal period 0.5H of the first half of the fourth period p4 may be respectively applied to the sub-pixel circuits connected to the data lines DL(2 h−3), DL2(h−1), and DL(2 h+1) among the sub-pixel circuits positioned in the (i−1)-th row. In addition, green data signals received from the output lines YL(h−1), YLh, and YL(h+1) during the 0.5 horizontal period 0.5H of the second half of the fourth period p4 may be respectively applied to the sub-pixel circuits connected to the data lines DL2(h−2), DL(2 h), and DL(2 h+2) among the sub-pixel circuits positioned in the (i−1)-th row.

In addition, during the 0.5 horizontal period 0.5H of the first half of the fifth period p5, the data signals from the output lines YL1 to YLk may be applied to the sub-pixel circuits positioned in the odd column of the i-th row, and during the 0.5 horizontal period 0.5H of the second half of the fifth period p5, the data signals from the output lines YL1 to YLk may be applied to the sub-pixel circuits positioned in the even column of the i-th row. That is, a blue data signal, a red data signal, and a blue data signal received from the output lines YL(h−1), YLh, and YL(h+1) during the 0.5 horizontal period 0.5H of the first half of the fifth period p5 may be respectively applied to the sub-pixel circuits connected to the data lines DL(2 h−3), DL2(h−1), and DL(2 h+1) among the sub-pixel circuits positioned in the i-th row. In addition, green data signals received from the output lines YL(h−1), YLh, and YL(h+1) during the 0.5 horizontal period 0.5H of the second half of the fifth period p5 may be respectively applied to the sub-pixel circuits connected to the data lines DL2(h−2), DL(2 h), and DL(2 h+2) among the sub-pixel circuits positioned in the i-th row.

In a similar manner, a red data signal, a blue data signal, and a red data signal received from the output lines YL(h−1), YLh, and YL(h+1) during the 0.5 horizontal period 0.5H of the first half of the sixth period p6 may be respectively applied to the odd-numbered sub-pixel circuits among the sub-pixel circuits positioned in the (i+1)-th row. In addition, green data signals received from the output lines YL(h−1), YLh, and YL(h+1) during the 0.5 horizontal period 0.5H of the second half of the sixth period p6 may be respectively applied to the even-numbered sub-pixel circuits among the sub-pixel circuits positioned in the (i+1)-th row.

In the subsequent seventh period p7 and eighth period p8, the data signal from the output lines YL(h−1), YLh, and YL(h+1) may be applied to sub-pixel circuits connected to an (i+2)-th row and an (i+3)-th row, respectively.

According to some embodiments, and as shown in FIG. 6, FIG. 13, FIG. 14, and FIG. 15, sub-pixel circuits corresponding to two columns may share each of the output lines YL1 to YLk connected to the data driver 251, without a demultiplexer being disposed between the data driver and the pixel unit. In a case where the demultiplexer and its transistors may be omitted, the area for manufacturing the display driver 201 may be reduced.

In addition, since the sub-pixel circuits may be directly connected to the k output lines YL1 to YLk, which number half the n data lines DL1 to DLn, instead of the n data lines DL1 to DLn, a number of output lines arranged in a vertical direction may be reduced.

According to an embodiment and as shown in FIGS. 13 to 15, even in the diamond type configuration of a PENTILE structure, complexity of the line connecting the light emitting elements and the sub-pixel circuits may be reduced.

However, as shown in FIG. 13, FIG. 14, and FIG. 15, the data driver 231 may be needed to output a data signal corresponding to different colors while changing the data signal for each period 0.5H corresponding to half of one horizontal period 1H to each of the output lines YL1 to YLk.

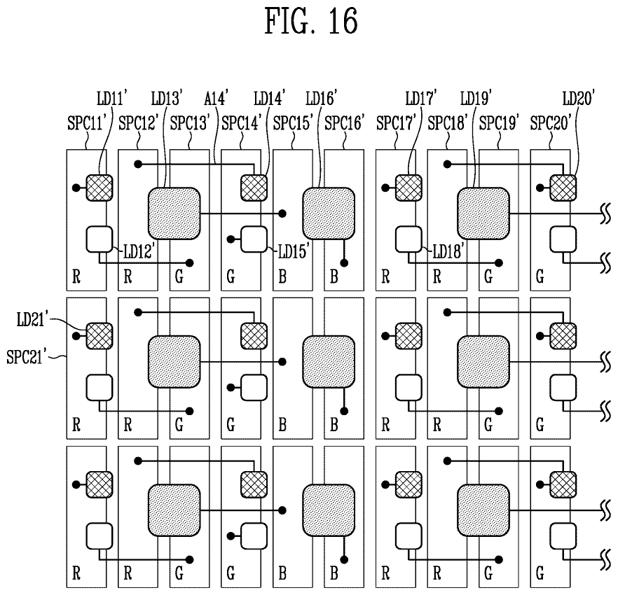

FIG. 16 is a diagram illustrating the pixel unit shown in FIG. 6 according to an embodiment.

The pixel unit of FIG. 7, FIG. 10, and FIG. 13 may include a diamond type configuration, such as the PENTILE structure. The pixel unit shown in FIG. 16 may include a sub-pixel disposition of an RGB stripe structure.

Referring to FIG. 16, thirty sub-pixel circuits and thirty-three light emitting elements are shown. Specifically, sub-pixels, light emitting elements respectively corresponding thereto, and additional light emitting elements are shown in a matrix form including three rows and ten columns.

For example, ten sub-pixel circuits SPC11′, SPC12′, SPC13′, . . . , and SPC20′ may be disposed in a first row. Red sub-pixel circuits SPC11′, SPC12′, SPC17′, and SPC18′ may be connected to red light emitting elements LD11′, LD14′, LD17′, and LD20′. Green sub-pixel circuits SPC13′, SPC14′, and SPC19′ may be connected to green light emitting elements LD12′, LD15′, and LD18′. Among the light emitting elements shown in FIG. 16, a green light emitting element directly under a red light emitting element LD20′ may be connected to the sub-pixel circuit SPC20′. Meanwhile, blue sub-pixel circuits SPC15′ and SPC16′ may be connected to blue light emitting elements LD13′ and LD16′. In addition, a blue light emitting element LD19′ may be connected to a sub-pixel circuit (not shown) positioned on a right side of the sub-pixel circuit SPC20′.

In addition, ten sub-pixel circuits SPC21′, . . . may be disposed in a second row, and these sub-pixel circuits may be respectively connected to corresponding light emitting elements LD21′, . . . . Meanwhile, ten sub-pixel circuits SPC21, . . . may be disposed in a third row, and ten light emitting elements LD21, . . . may be respectively connected to them.

Referring to FIG. 16, all sub-pixel circuits positioned in the first, second, and third rows may be disposed in an order such that they may be connected to light emitting elements that display colors of “R R G G B B R R G G”.

For example, the anode electrode A14′ connecting the light emitting element LD14′ and the sub-pixel circuit corresponding thereto, i.e., the sub-pixel circuit SPC12′, may be disposed on the sub-pixel circuits SPC13′ and SPC14′ that are not connected to the light emitting element LD14′.

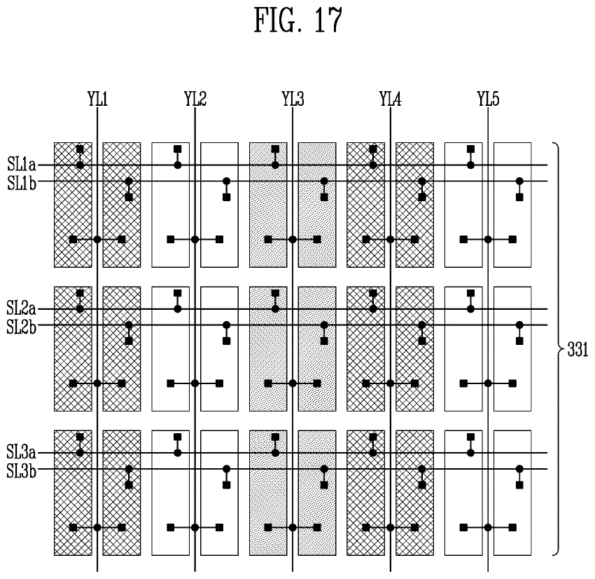

An output line and a scan line connected to each of the sub-pixel circuits shown in FIG. 16 are described with reference to FIG. 17.

FIG. 17 is a diagram illustrating the output line and the scan line connected to the sub-pixel circuits shown in FIG. 16.

Referring to FIG. 17, the thirty sub-pixel circuits shown in FIG. 16 are shown. For convenience of discussion, the light emitting elements may be omitted in FIG. 17. As described herein, the sub-pixel circuits positioned in the rows may be disposed in the order such that they may be connected to the light emitting elements that display the colors of “R R G G B B R R G G”.

According to an embodiment and as shown in FIG. 17, the connection relationship between the output lines YL1 to YL5 and each of the sub-pixel circuits may be the same as that shown in FIG. 8. In addition, as shown in FIG. 17, the connection relationship between the first scan lines SL1a, SL2a, and SL3a and the second scan lines SL1b, SL2b, and SL3b, and each of the sub-pixel circuits may also be the same as that shown in FIG. 8. However, the light emitting element to which each of the sub-pixel circuits is connected may be different from that shown in FIG. 7 and FIG. 8. As shown in FIG. 8, the sub-pixel circuits of the first column and the second column and the sub-pixel circuits of the ninth column and the tenth column may be connected to the light emitting element that emits red light. However, as shown in FIG. 17, the sub-pixel circuits of the first column and the second column and the sub-pixel circuits of the seventh column and the eighth column may be connected to the light emitting element that emits red light.

In addition, as shown in FIG. 8, the sub-pixel circuits of the third column and the fourth column and the sub-pixel circuits of the seventh column and the eighth column may be connected to the light emitting element that emits green light. However, as shown in of FIG. 17, the sub-pixel circuits of the third column and the fourth column and the sub-pixel circuits of the ninth column and the tenth column may be connected to the light emitting element that emits green light.

As shown in both FIG. 8 and FIG. 17, the sub-pixel circuits of the fifth column and the sixth column may be connected to the light emitting element that emits blue light.

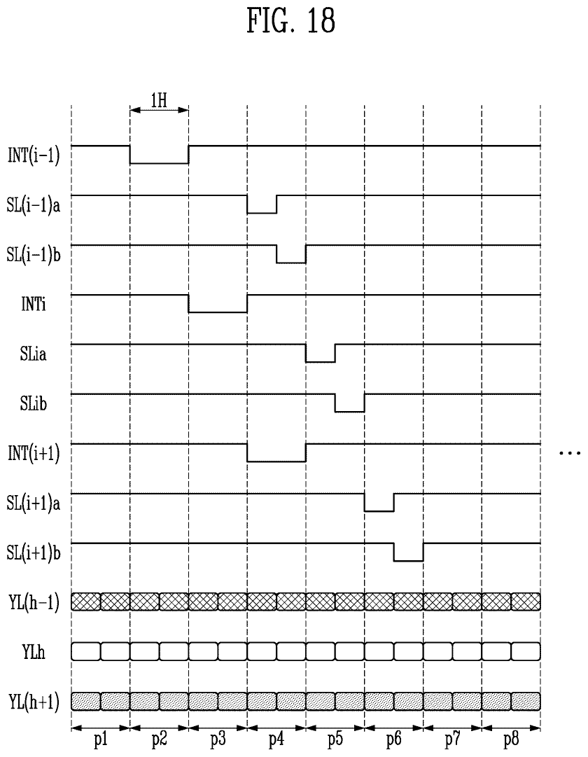

An operation of the pixel unit shown in FIG. 16 and FIG. 17 is described with reference to FIG. 18.

FIG. 18 is a timing diagram illustrating the operation of the display device according to FIG. 16 and FIG. 17.

Referring to FIG. 18, during the entire period, signals of an initialization line INT(i−1), a first scan line SL(i−1)a, and a second scan line SL(i−1) b connected to the sub-pixel circuits of the (i−1)-th row, an initialization line INTi, a first scan line SLia, and a second scan line SLib connected to the sub-pixel circuits of the i-th row, and an initialization line INT(i+1), a first scan line SL(i+1)a, and a second scan line SL(i+1)b connected to the sub-pixel circuits of the (i+1)-th row may be the same as those shown in FIG. 9 or FIG. 12. Therefore, redundant descriptions overlapping those of FIG. 9 and FIG. 12 may be omitted.

In addition, in FIG. 18, a type of data output to the output lines YL(h−1), YLh, and YL(h+1) during the entire period may be the same as that shown in FIG. 9. However, a type of data output to an output line following the output line YL(h+1) may be different from that of FIG. 9.

Specifically, since FIG. 9 relates to an example PENTILE structure, although not shown in FIG. 9, a green data signal may be output to the output line following the output line YL(h+1). On the other hand, since FIG. 18 relates to an example RGB stripe structure, although not shown in FIG. 18, a red data signal may be output to the output line following the output line YL(h+1).

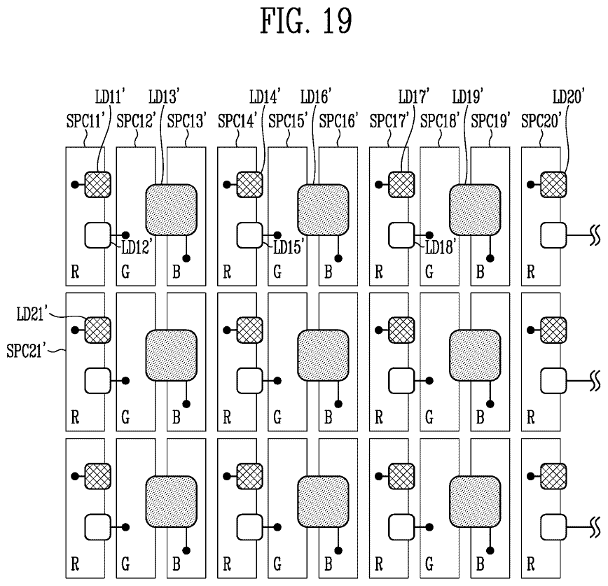

FIG. 19 is a diagram illustrating the pixel unit shown in FIG. 6 according to an embodiment.

Referring to FIG. 19, the pixel unit shown in FIG. 19 may include the sub-pixel disposition of the RGB stripe structure similar to FIG. 16. Meanwhile, as shown in FIG. 19, since each of the light emitting elements may be connected to a directly adjacently positioned pixel circuit, complexity of a line connection for connecting the light emitting elements and the sub-pixel circuits may be reduced, even in the RGB stripe structure.

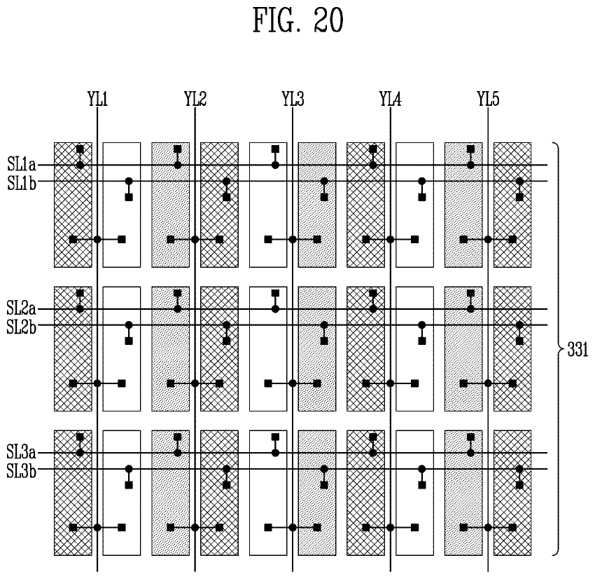

FIG. 20 is a diagram illustrating the output line and the scan line connected to the sub-pixel circuits shown in FIG. 13.

Referring to FIG. 20, the sub-pixel circuits of the first column, the fourth column, and the tenth column may be the red sub-pixel circuits, the sub-pixel circuits of the second column, the fifth column, and the eighth column may be the green sub-pixel circuits, and the sub-pixel circuit of the third column, the sixth column, and the ninth column may be the blue sub-pixel circuit. Therefore, an output line may be used to alternately output a data signal corresponding to two colors.

An operation of the pixel unit shown in FIG. 19 and FIG. 20 is described with reference to FIG. 18.

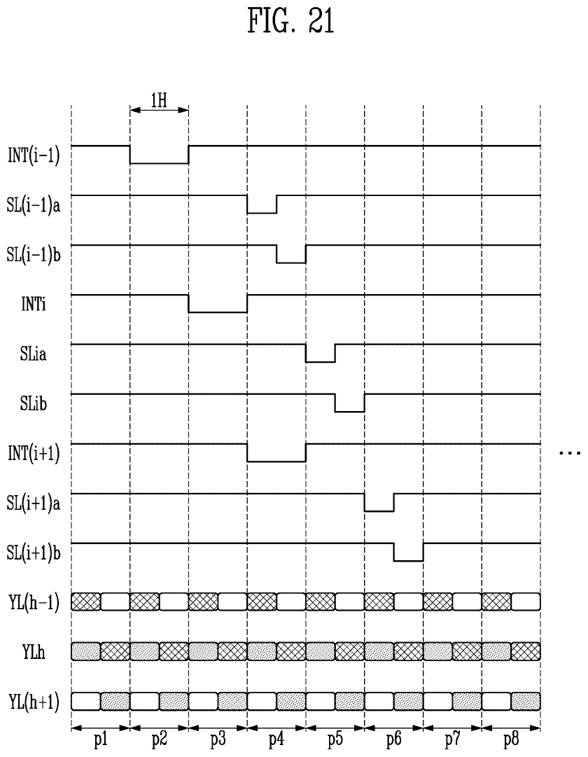

FIG. 21 is a timing diagram illustrating an operation of the display device of FIG. 16 and FIG. 17 according to an embodiment.

Referring to FIG. 21, during the entire period, signals of an initialization line INT(i−1), a first scan line SL(i−1)a, and a second scan line SL(i−1) b connected to the sub-pixel circuits of the (i−1)-th row, an initialization line INTi, a first scan line SLia, and a second scan line SLib connected to the sub-pixel circuits of the i-th row, and an initialization line INT(i+1), a first scan line SL(i+1)a, and a second scan line SL(i+1)b connected to the sub-pixel circuits of the (i+1)-th row may be the same as those shown in FIG. 9 or FIG. 12. Therefore, redundant descriptions overlapping those of FIG. 9 and FIG. 12 may be omitted.

In addition, in FIG. 21, during the entire period, the output line YL(h−1) may alternately output red and green data signals, and output line YLh may alternately output blue and red data signals, and the output line YL(h+1) may alternately output green and blue data signals.

FIG. 16, FIG. 17, and FIG. 18 show a line structure connecting the sub-pixel circuit and the light emitting element that may be relatively simple, but each output line may alternately output data corresponding to different colors.

The drawings referred to so far and the detailed description of the disclosure described herein are merely examples of the disclosure. The drawings are used for merely describing aspects of the disclosure, and are not intended to limit the meaning and the scope of the disclosure or claims. Therefore, those skilled in the art will understand that various modifications and equivalent other embodiments are possible.

What is claimed is:

1. A display device comprising:
a plurality of sub-pixel circuits disposed in a matrix form including a plurality of rows and a plurality of columns;
a plurality of light emitting elements respectively connected to the plurality of sub-pixel circuits;
a plurality of output lines configured to carry a data signal to the plurality of sub-pixel circuits; and
a plurality of first scan lines and a plurality of second scan lines configured to carry a scan signal to the plurality of sub-pixel circuits,
wherein each of the plurality of output lines is commonly connected to sub-pixel circuits, among the plurality of sub-pixel circuits, disposed in different columns among the plurality of columns,
each of the plurality of first scan lines is connected to first sub-pixel circuits of a corresponding row among the plurality of sub-pixel circuits, and
each of the plurality of second scan lines is connected to second sub-pixel circuits of a corresponding row among the plurality of sub-pixel circuits, wherein the first sub-pixel circuits and the second sub-pixel circuits are alternately disposed in the corresponding row.

2. The display device according to claim 1, further comprising:
a data driver outputting the data signal to the plurality of sub-pixel circuits through the plurality of output lines; and
a scan driver outputting the scan signal to the plurality of sub-pixel circuits through the plurality of first scan lines and the plurality of second scan lines,
wherein the plurality of rows include m rows and the plurality of columns includes n columns,
a number of the plurality of first scan lines is m, a number of the plurality of second scan lines is m, the number of the plurality of output lines is n/2,
during a horizontal period corresponding to a selected row among the plurality of rows, the scan driver activates a voltage of a first scan line corresponding to the selected row among the plurality of first scan lines during a first period of the horizontal period, and activates a voltage of a second scan line corresponding to the selected row of the plurality of second scan lines during a second period different from the first period of the horizontal period, and
m and n are integers greater than or equal to 2.

3. The display device according to claim 2, wherein during the first period, data output to the plurality of output lines is applied to a first sub-pixel circuit among the first sub-pixel circuits corresponding to the selected row, and
during the second period, data output to the plurality of output lines is applied to a second sub-pixel circuit among the second sub-pixel circuits corresponding to the selected row.

4. The display device according to claim 3, wherein the data driver is configured to apply data corresponding to a first color to sub-pixel circuits connected to a first output line among the plurality of output lines.

5. The display device according to claim 4, wherein the data driver is configured to apply data corresponding to a second color to sub-pixel circuits connected to a second output line among the plurality of output lines.

6. The display device according to claim 1, wherein the plurality of light emitting elements are formed on the plurality of sub-pixel circuits, and
an anode electrode connecting a light emitting element among the plurality of light emitting elements and a corresponding sub-pixel circuit is disposed on at least two sub-pixel circuits of the plurality of sub-pixel circuits.

7. The display device according to claim 3, wherein the data driver is configured to apply data corresponding to a same color to sub-pixel circuits connected to a first output line among the plurality of output lines and apply data corresponding to different colors to sub-pixel circuits connected to a second output line among the plurality of output lines.

8. The display device according to claim 7, wherein the plurality of light emitting elements are formed on the plurality of sub-pixel circuits, and
an anode electrode connecting a light emitting element among the plurality of light emitting elements and a corresponding sub-pixel circuit is disposed on a sub-pixel circuit that is not connected to the light emitting element.

9. The display device according to claim 3, wherein the data driver is configured to apply data corresponding to different colors to sub-pixel circuits connected to each of the plurality of output lines.

10. The display device according to claim 9, wherein the plurality of light emitting elements are formed on the plurality of sub-pixel circuits, and
the display device further comprises a plurality of anode electrodes connecting each of the plurality of light emitting elements and a respective sub-pixel circuit disposed directly adjacent thereto.

11. The display device according to claim 1, wherein the plurality of light emitting elements are disposed in one of an RGBG structure or an RGB stripe structure.

12. A display device comprising:
a data driver outputting data to k output lines;
a scan driver outputting a scan signal to m first scan lines and m second scan lines; and
a pixel unit connected to the k output lines, first scan lines, and second scan lines,
wherein the pixel unit comprises:
a plurality of sub-pixel circuits disposed in a matrix form including m rows and 2k columns,
a plurality of light emitting elements respectively connected to the plurality of sub-pixel circuits,
wherein an h-th output line among the k output lines is commonly connected to sub-pixel circuits positioned in a (2 h−1)-th column and a 2 h-th column among the plurality of sub-pixel circuits,
an i-th first scan line among the first scan lines is connected to first sub-pixel circuits among sub-pixel circuits positioned in an i-th row,
an i-th second scan line among the second scan lines is connected to second sub-pixel circuits among the sub-pixel circuits positioned in the i-th row, wherein the first sub-pixel circuits and the second sub-pixel circuits are alternately disposed in the i-th row, and
m and n are integers greater than or equal to 2, k is an integer greater than or equal to 1, h is an integer greater than 0 and less than or equal to k, and i is an integer greater than 0 and less than or equal to m.

13. The display device according to claim 12, wherein the data driver is configured to apply data corresponding to a same color during a plurality of horizontal periods to sub-pixel circuits connected to each of at least one output line among the k output lines.

14. The display device according to claim 13, wherein the plurality of light emitting elements are formed on the plurality of sub-pixel circuits, and
an anode electrode connecting a light emitting element among the plurality of light emitting elements and a corresponding sub-pixel circuit is disposed on a sub-pixel circuit of the plurality of sub-pixel circuits that is not connected to the light emitting element.

15. The display device according to claim 13, wherein the data driver is configured to apply data corresponding to the same color during a plurality of horizontal periods to sub-pixel circuits connected to each of the k output lines.

16. The display device according to claim 15, wherein the plurality of light emitting elements are formed on the plurality of sub-pixel circuits, and
an anode electrode connecting a light emitting element among the plurality of light emitting elements and a corresponding sub-pixel circuit is disposed on at least two sub-pixel circuits of the plurality of sub-pixel circuits that are not connected to the light emitting element.

17. The display device according to claim 12, wherein the data driver is configured to apply data corresponding to different colors to sub-pixel circuits connected to each of the k output lines.

18. The display device according to claim 12, wherein the plurality of light emitting elements are disposed in one of an RGBG structure or RGB stripe structure.

19. A display device comprising:
a plurality of sub-pixel circuits disposed in a matrix form including a plurality of rows and a plurality of columns;
a plurality of light emitting elements respectively connected to the plurality of sub-pixel circuits;
a data driver outputting a data signal to the plurality of sub-pixel circuits through a plurality of output lines; and
a scan driver outputting a scan signal to the plurality of sub-pixel circuits through a plurality of first scan lines and a plurality of second scan lines;
wherein each output line among the plurality of output lines is commonly connected to sub-pixel circuits of the plurality of sub-pixel circuits positioned in adjacent columns among the plurality of columns,
each of the plurality of first scan lines is connected to first sub-pixel circuits of a corresponding row among the plurality of sub-pixel circuits,
each of the plurality of second scan lines is connected to second sub-pixel circuits of a corresponding row among the plurality of sub-pixel circuits, wherein the first sub-pixel circuits and the second sub-pixel circuits are alternately disposed in the corresponding row, and
an anode electrode connecting a light emitting element among the plurality of light emitting elements and a corresponding sub-pixel circuit is disposed on a sub-pixel circuit of the plurality of sub-pixel circuits that is not connected to the light emitting element.

20. The display device according to claim 19, wherein the anode electrode connecting the light emitting element and the corresponding sub-pixel circuit is disposed on at least two sub-pixel circuits of the plurality of sub-pixel circuits that are not connected to the light emitting element.
